(19) United States
(12) Patent Application Publication
(10) Pub. No.: US 2026/0343948 A1
(43) Pub. Date: Oct. 29, 2026

(54) DISPLAY DEVICE AND ELECTRONIC DEVICE HAVING THE SAME

(71) Applicant: Samsung Display Co., Ltd., Yongin-si (KR)

(72) Inventors: Eok Su KIM, Yongin-si (KR); Sunhee LEE, Yongin-si (KR)

(73) Assignee: Samsung Display Co., Ltd., Yongin-si (KR)

(21) Appl. No.: 19/461,059

(22) Filed: Jan. 27, 2026

(30) Foreign Application Priority Data
Apr. 24, 2025 (KR) 10-2025-0053818

(51) Int. Cl. H10D 30/67; H10D 86/40; H10D 86/60; H10K 59/121; H10K 59/123; H10K 59/124

(52) U.S. Cl. CPC H10D 30/6734; H10D 86/423; H10D 86/60; H10K 59/123; H10K 59/124; H10K 59/1213

(57) ABSTRACT

A display device includes a first transistor. The first transistor includes a first oxide semiconductor pattern including a first input region, a first output region, and a first channel region disposed between the first input region and the first output region, a first gate electrode disposed above the first channel region and overlapping the first channel region on a plane, a (1-1)-th gate electrode disposed below the first channel region, overlapping the first channel region on a plane, and electrically connected to the first output region, and a (1-2)-th gate electrode disposed below the first channel region, overlapping the first channel region on a plane, and electrically connected to the first output region. The (1-1)-th gate electrode and the (1-2)-th gate electrode are disposed at different layers.

### CROSS-REFERENCE TO RELATED APPLICATIONS

This U.S. non-provisional patent application claims priority under 35 U.S.C. § 119 of Korean Patent Application No. 10-2025-0053818, filed on Apr. 24, 2025, the entire contents of which are hereby incorporated by reference.

### BACKGROUND

The present inventive concepts herein relate to display devices and electronic devices including the same, and to display devices having an oxide transistor and electronic devices including the display devices.

A display device may include a plurality of pixels and a driving circuit (e.g., a scan driving circuit and a data driving circuit) which controls the plurality of pixels. Each pixel of the plurality of pixels may include a display element and a pixel circuit which controls the display element. The pixel circuit may include a plurality of organically connected transistors.

The plurality of transistors may include a silicon semiconductor or a metal oxide transistor.

### SUMMARY

Some example embodiments of the present inventive concepts provide a display device with improved driving characteristics.

Some example embodiments of the present inventive concepts provide an electronic device including the display device.

A display device according to some example embodiments of the present inventive concepts may include a base layer, a plurality of insulating layers on the base layer, a first transistor on the base layer, and a light emitting element electrically connected to the first transistor. The first transistor may include a first oxide semiconductor pattern that includes a first input region, a first output region, and a first channel region between the first input region and the first output region, a first gate electrode above the first channel region and at least partially overlapping the first channel region in a vertical direction extending perpendicular to a top surface of the base layer, a (1-1)-th gate electrode disposed below the first channel region and at least partially overlapped by the first channel region in the vertical direction and electrically connected to the first output region and electrically connected to the first output region, and a (1-2)-th gate electrode below the first channel region and at least partially overlapped by the first channel region in the vertical direction and electrically connected to the first output region. The (1-1)-th gate electrode and the (1-2)-th gate electrode may be at different layers such that one of the (1-1)-th gate electrode or the (1-2)-th gate electrode is closer to the top surface of the base layer than another one of the (1-1)-th gate electrode or the (1-2)-th gate electrode in the vertical direction.

The display device according to some example embodiments of the present inventive concepts may further include a connection electrode that is on the base layer and configured to electrically connect the first output region, the (1-1)-th gate electrode, and the (1-2)-th gate electrode.

The plurality of insulating layers may include a first insulating layer on the (1-1)-th gate electrode, a second insulating layer on the first insulating layer and the (1-2)-th gate electrode such that the first insulating layer is between the (1-1)-th gate electrode and both the second insulating layer and the (1-2)-th gate electrode in the vertical direction, and a third insulating layer on the second insulating layer and the first oxide semiconductor pattern.

The connection electrode may be connected to the (1-1)-th gate electrode through a first contact hole passing through the first insulating layer, the second insulating layer, and the third insulating layer. The connection electrode may be connected to the (1-2)-th gate electrode through a second contact hole passing through the second insulating layer and the third insulating layer. The connection electrode may be connected to the first output region through a third contact hole passing through the third insulating layer.

The first contact hole and the second contact hole may be spaced apart from the first gate electrode and the first oxide semiconductor pattern in one or more horizontal directions extending parallel to the top surface of the base layer.

The (1-1)-th gate electrode may be closer than the (1-2)-th gate electrode to the base layer in the vertical direction. A first portion of the (1-1)-th gate electrode may be at least partially overlapped by the first input region in the vertical direction, and a second portion of the (1-1)-th gate electrode may be at least partially overlapped by the first channel region in the vertical direction. A first portion of the (1-2)-th gate electrode may be at least partially overlapped by the first output region in the vertical direction, and a second portion of the (1-2)-th gate electrode may be at least partially overlapped by the first channel region in the vertical direction.

The (1-1)-th gate electrode may be closer than the (1-2)-th gate electrode to the base layer in the vertical direction. A first portion of the (1-1)-th gate electrode may be at least partially overlapped by the first output region in the vertical direction, and a second portion of the (1-1)-th gate electrode may be at least partially overlapped by the first channel region in the vertical direction. A first portion of the (1-2)-th gate electrode may be at least partially overlapped by the first input region in the vertical direction, and a second portion of the (1-2)-th gate electrode may be at least partially overlapped by the first channel region in the vertical direction.

The (1-1)-th gate electrode may be closer than the (1-2)-th gate electrode to the base layer in the vertical direction. The (1-1)-th gate electrode may include a first portion at least partially overlapped by the first input region in the vertical direction, a second portion at least partially overlapped by the first channel region in the vertical direction, and a third portion at least partially overlapped by the first output region in the vertical direction. The (1-2)-th gate electrode may include a first portion at least partially overlapped by the first input region or the first output region in the vertical direction and a second portion at least partially overlapped by the first channel region in the vertical direction.

A portion of the (1-1)-th gate electrode and a portion of the (1-2)-th gate electrode may at least partially overlap each other in the vertical direction.

The (1-1)-th gate electrode and the (1-2)-th gate electrode may be spaced apart from each other in one or more horizontal directions extending parallel to the top surface of the base layer.

The display device according to some example embodiments of the present inventive concepts may further include a second transistor on the base layer. The second transistor may include a second oxide semiconductor pattern that includes a second input region, a second output region, and a second channel region between the second input region and the second output region, a second gate electrode above the second channel region and overlapping the second channel region in the vertical direction, and a (2-1)-th gate electrode below the second channel region and at least partially overlapped by the second channel region in the vertical direction and electrically connected to the second gate electrode. A first separation distance in the vertical direction between the first channel region and the (1-2)-th gate electrode may be smaller than a second separation distance in the vertical direction between the second channel region and the (2-1)-th gate electrode.

The (2-1)-th gate electrode may be at a same layer and include a same material as the (1-1)-th gate electrode.

The display device according to some example embodiments of the present inventive concepts may further include a connection electrode which connects the second gate electrode and the (2-1)-th gate electrode. The plurality of insulating layers may include first and second insulating layers on the (2-1)-th gate electrode, and a third insulating layer on the second oxide semiconductor pattern and the second gate electrode. A portion of the connection electrode may be on the third insulating layer.

The display device according to some example embodiments of the present inventive concepts may further include a capacitor electrically connected between the first lower gate electrode and the first channel region.

An electronic device according to some example embodiments of the present inventive concepts may include a display device and a processor which controls the display device. The display device may include a base layer, a plurality of insulating layers on the base layer, a first transistor on the base layer, and a light emitting element electrically connected to the first transistor. The first transistor may include a first oxide semiconductor pattern that may include a first input region, a first output region, and a first channel region between the first input region and the first output region, a first gate electrode above the first channel region and at least partially overlapping the first channel region in a vertical direction extending perpendicular to a top surface of the base layer, a (1-1)-th gate electrode below the first channel region and at least partially overlapped by the first channel region in the vertical direction and electrically connected to the first output region, and a (1-2)-th gate electrode below the first channel region and at least partially overlapped by the first channel region in the vertical direction and electrically connected to the first output region. The (1-1)-th gate electrode and the (1-2)-th gate electrode may be at different layers such that one of the (1-1)-th gate electrode or the (1-2)-th gate electrode is closer to the top surface of the base layer than another one of the (1-1)-th gate electrode or the (1-2)-th gate electrode in the vertical direction.

The electronic device according to some example embodiments of the present inventive concepts may further include a connection electrode that is on the base layer and configured to electrically connect the first channel region, the (1-1)-th gate electrode, and the (1-2)-th gate electrode.

The (1-1)-th gate electrode may be closer than the (1-2)-th gate electrode to the base layer in the vertical direction. A first portion of the (1-1)-th gate electrode may be at least partially overlapped by the first input region in the vertical direction, and a second portion of the (1-1)-th gate electrode may be at least partially overlapped by the first channel region in the vertical direction. A first portion of the (1-2)-th gate electrode may be at least partially overlapped by the first output region in the vertical direction, and a second portion of the (1-2)-th gate electrode may be at least partially overlapped by the first channel region in the vertical direction.

The (1-1)-th gate electrode may be closer than the (1-2)-th gate electrode to the base layer in the vertical direction. A first portion of the (1-1)-th gate electrode may be at least partially overlapped by the first output region in the vertical direction, and a second portion of the (1-1)-th gate electrode may be at least partially overlapped by the first channel region in the vertical direction. A first portion of the (1-2)-th gate electrode may be at least partially overlapped by the first input region in the vertical direction, and a second portion of the (1-2)-th gate electrode may be at least partially overlapped by the first channel region in the vertical direction.

The (1-1)-th gate electrode may be closer than the (1-2)-th gate electrode to the base layer in the vertical direction. The (1-1)-th gate electrode may include a first portion at least partially overlapped by the first input region in the vertical direction, a second portion at least partially overlapped by the first channel region in the vertical direction, and a third portion at least partially overlapped by the first output region in the vertical direction. The (1-2)-th gate electrode may include a first portion at least partially overlapped by the first input region or the first output region in the vertical direction, and a second portion at least partially overlapped by the first channel region in the vertical direction.

The electronic device according to some example embodiments of the present inventive concepts may further include a second transistor on the base layer. The second transistor may include a second oxide semiconductor pattern including a second input region, a second output region, and a second channel region between the second input region and the second output region, a second gate electrode above the second channel region and overlapping the second channel region in the vertical direction, and a (2-1)-th gate electrode below the second channel region, the (2-1)-th gate electrode at least partially overlapped by the second channel region in the vertical direction and electrically connected to the second gate electrode. A first separation distance in the vertical direction between the first channel region and the (1-2)-th gate electrode is smaller than a second separation distance in the vertical direction between the second channel region and the (2-1)-th gate electrode.

### BRIEF DESCRIPTION OF THE DRAWINGS

FIG. 1A is a block diagram of an electronic device according to some example embodiments of the present inventive concepts.

FIG. 1B is a schematic view of electronic devices according to some example embodiments of the present inventive concepts.

FIG. 2 is a block diagram of a display device according to some example embodiments of the present inventive concepts.

FIG. 3A is an equivalent circuit diagram of a pixel according to some example embodiments of the present inventive concepts.

FIG. 3B is a waveform diagram of driving signals for driving the pixel illustrated in FIG. 3A according to some example embodiments of the present inventive concepts.

FIG. 4A is a cross-sectional view of a display panel according to some example embodiments of the present inventive concepts.

FIG. 4B is a voltage-current graph of a first transistor according to some example embodiments of the present inventive concepts.

FIG. 4C is a cross-sectional view of a display panel according to some example embodiments of the present inventive concepts.

FIG. 5A is a plan view of a first transistor according to some example embodiments of the present inventive concepts.

FIG. 5B is a cross-sectional view of a first transistor according to some example embodiments of the present inventive concepts.

FIG. 5C is a cross-sectional view of a second transistor according to some example embodiments of the present inventive concepts.

FIGS. 6A and 6B are each a cross-sectional view of a display panel according to some example embodiments of the present inventive concepts.

FIG. 7A is a plan view of a first transistor according to some example embodiments of the present inventive concepts.

FIG. 7B is a first cross-sectional view of a first transistor according to some example embodiments of the present inventive concepts.

FIG. 7C is a second cross-sectional view of a first transistor according to some example embodiments of the present inventive concepts.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element below could be termed a second element without departing from the scope of the present inventive concepts. Similarly, a second element could be termed a first element. The singular expressions are intended to include the plural forms as well, unless the context clearly indicates otherwise.

In addition, the terms “below”, “on the lower side”, “above”, “on the upper side”, or the like may be used to describe the relationships between the elements illustrated in the drawings. These terms are relative concepts and are described on the basis of the directions indicated in the drawings.

It will be further understood that the terms such as “comprises”, includes”, “has”, when used in this specification, specify the presence of stated features, numbers, steps, operations, elements, components or combinations thereof, but do not preclude the possibility of the presence or addition of one or more other features, numbers, steps, operations, elements, components, or combinations thereof.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” or the like, respectively, with regard to the other elements and/or properties thereof.

Elements and/or properties thereof (e.g., structures, surfaces, directions, or the like) that are “substantially perpendicular” or “substantially parallel” with regard to other elements and/or properties thereof will be understood to be “perpendicular” or “parallel”, respectively, with regard to the other elements and/or properties thereof within manufacturing tolerances and/or material tolerances and/or have a deviation in magnitude and/or angle from “perpendicular” or “parallel”, respectively, with regard to the other elements and/or properties thereof that is equal to or less than 10% (e.g., a tolerance of ±10%).

It will be understood that elements and/or properties thereof may be recited herein as being “the same” as other elements and/or properties thereof, and it will be further understood that elements and/or properties thereof recited herein as being “the same” as other elements and/or properties thereof may be “the same” as or “substantially the same” as the other elements and/or properties thereof. Elements and/or properties thereof that are “substantially the same” as other elements and/or properties thereof will be understood to include elements and/or properties thereof that are the same as the other elements and/or properties thereof within manufacturing tolerances and/or material tolerances. Elements and/or properties thereof that are the same or substantially the same as other elements and/or properties thereof may be structurally the same or substantially the same, functionally the same or substantially the same, and/or compositionally the same or substantially the same.

While the term “same” may be used in the description of some example embodiments, it should be understood that some imprecisions may exist. Thus, when one element or property is referred to as being the same as another element or property, it should be understood that the element or property is the same as another element or property within a desired manufacturing or operational tolerance range (e.g., ±10%).

It will be understood that elements and/or properties thereof described herein as being “substantially” the same as one or more other elements and/or properties thereof encompasses elements and/or properties thereof that have a relative difference in magnitude with the one or more other elements and/or properties thereof that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

Hereinafter, some example embodiments of the present inventive concepts are described with reference to the accompanying drawings.

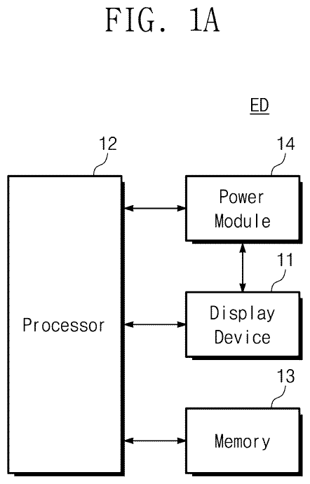

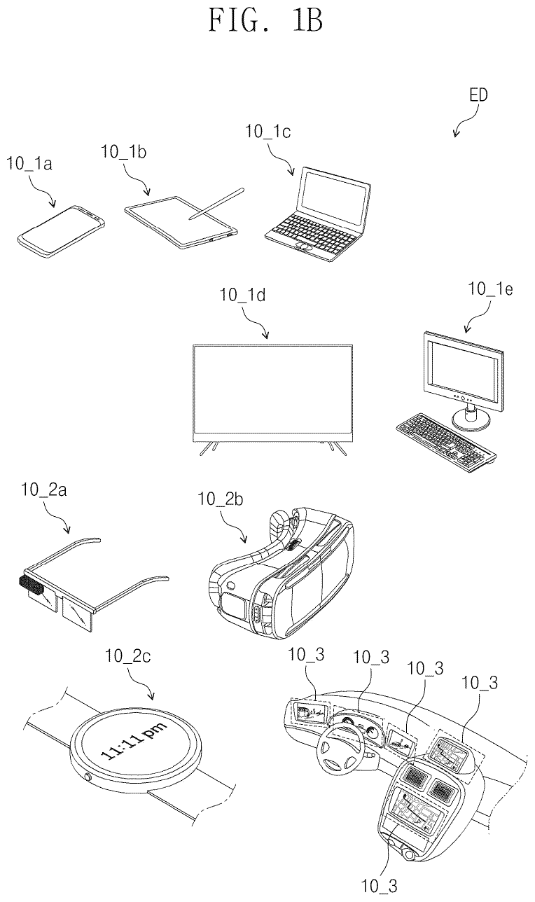

FIG. 1A is a block diagram of an electronic device ED according to some example embodiments of the present inventive concepts. FIG. 1B is a schematic view of electronic devices ED according to some example embodiments of the present inventive concepts.

Referring to FIG. 1A, the electronic device ED according to some example embodiments may include a display device 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for an operation of the processor 12 or the display device 11, including for example a program of instructions. The processor 12 may execute an application (e.g., a program of instructions) stored in the memory 13, to cause an image data signal and/or an input control signal to be transmitted to the display device 11, and the display device 11 may process the received signal and output (transmit) image information through a display screen. That is, the processor 12 may control the operation of the display device 11.

The power module 14 may include a power supply module such as a power adapter or a battery device, and a power conversion module which converts the power supplied by the power supply module and generates power necessary for an operation of the electronic device ED.

The processor 12, the power module 14, the memory 13, described above, may be included in the display device 11 or be separated as separate modules from the display device 11. The processor 12, the power module 14, the memory 13 may be provided in forms separated from the display device 11 inside a housing constituting an outer appearance of the electronic device ED.

Referring to FIG. 1B, the electronic device ED according to some example embodiments of the present inventive concepts may include not only typical electronic devices for informational purposes, such as a smartphone 10_1a, a tablet PC 10_1b, a laptop computer 10_1c, TV 10_1d, and a monitor for a desk computer 10_1e, but also wearable electronic devices such as smart glasses 10_2a, a head mounted display device 10_2b, and a smart watch 10_2c, and vehicle electronic devices 10_3 such as a vehicle instrument panel, a center fascia, a center information display (CID) disposed on a dashboard, and a room mirror display.

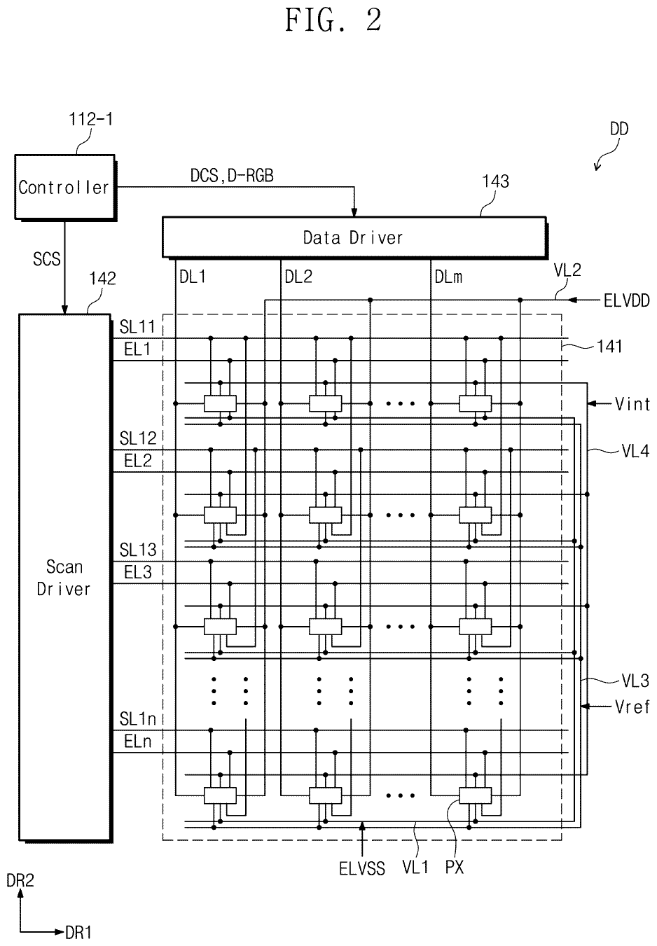

FIG. 2 is a block diagram of a display device DD according to some example embodiments of the present inventive concepts. Hereinafter, the display device 11 described with reference to FIG. 1A is described as the display device DD. In addition, a controller 112-1 to be described later will be a part of the processor 12 described above.

The display device DD may include the controller 112-1, a display panel 141, a scan driver 142, and a data driver 143. In some example embodiments, including the example embodiments shown in FIG. 2, the display panel 141 is described as an emissive display panel. The emissive display panel may include an organic light emitting display panel or an inorganic light emitting display panel.

The controller 112-1 converts a data format of image signals to match an interface specification of the scan driver 142 and generates image data D-RGB. The controller 112-1 outputs the image data D-RGB and various control signals DCS and SCS.

The scan driver 142 receives a scan control signal SCS from the controller 112-1. The scan control signal SCS may include a vertical start signal which starts an operation of the scan driver 142, a clock signal which determines output timing of signals, and the like. The scan driver 142 generates a plurality of scan signals and sequentially outputs the scan signals to corresponding scan lines SL11 to SL1n. In addition, the scan driver 142 generates a plurality of emission control signals in response to the scan control signal SCS and outputs a plurality of emission control signals to corresponding emission signal lines EL1 to ELn.

The plurality of scan signals and the plurality of emission control signals are illustrated as being output from one scan driver 142 in FIG. 2, but the present inventive concepts are not limited thereto. In some example embodiments of the present inventive concepts, the display device DD may further include a plurality of scan driving circuits. In addition, in some example embodiments of the present inventive concepts, a driving circuit which generates and outputs the plurality of scan signals, and a driving circuit which generates and outputs the plurality of emission control signals may be provided separately.

The data driver 143 receives a data control signal DCS and the image data D-RGB from the controller 112-1. The data driver 143 converts the image data D-RGB to data signals and outputs the data signals to a plurality of data lines DL1 to DLm to be described later. The data signals are analog voltages corresponding to a grayscale level of the image data D-RGB. Here, each of n and m is independently an integer greater than or equal to 1.

The display panel 141 may include a plurality of groups of scan lines. As an example, FIG. 2 illustrates a first group of scan lines SL11 to SL1n. The display panel 141 further includes the emission signal lines EL1 to ELn, the data lines DL1 to DLm, a first voltage line VL1, a second voltage line VL2, a third voltage line VL3, a fourth voltage line VL4, and a plurality of pixels PX.

The first group of scan lines SL11 to SL1n may extend in a first direction DR1 and be aligned in a second direction DR2. The data lines DL1 to DLm may cross the first group of scan lines SL11 to SL1n.

The first voltage line VL1 receives a first power voltage ELVSS. The second voltage line VL2 receives a second power voltage ELVDD. The second power voltage ELVDD has a higher level (e.g., a greater voltage magnitude) than the first power voltage ELVSS. The third voltage line VL3 receives a reference voltage Vref (hereinafter referred to as a first voltage). The fourth voltage line VL4 receives an initialization voltage Vint (hereinafter referred to as a second voltage). The first voltage Vref has a lower level than the second power voltage ELVDD. The second voltage Vint has a lower level than the second power voltage ELVDD. In this embodiment, the second voltage Vint may have a lower level than the first voltage Vref and the first power voltage ELVSS.

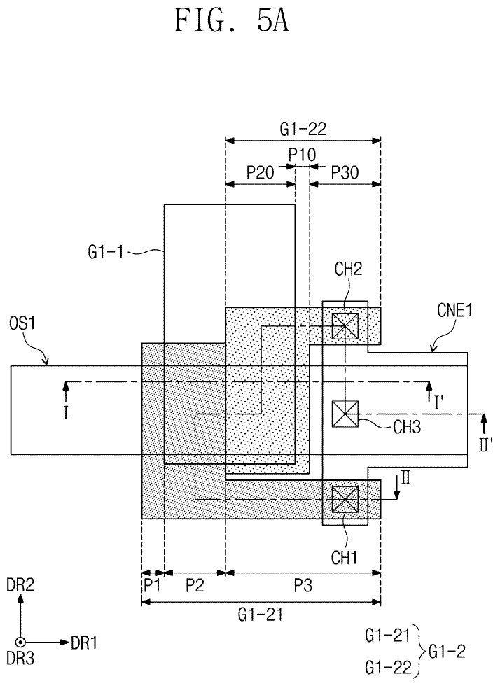

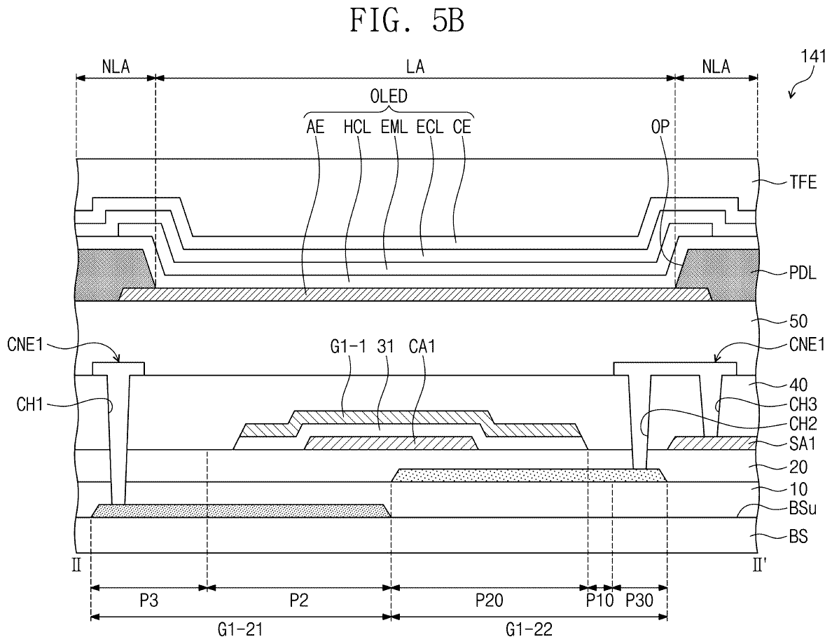

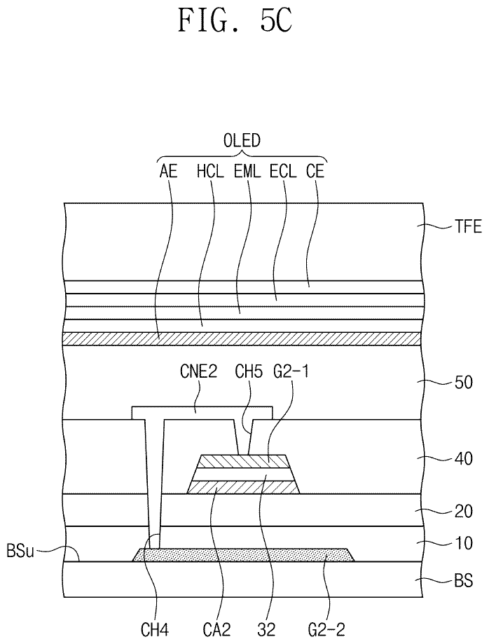

At least one of the first voltage line VL1, the second voltage line VL2, the third voltage line VL3, or the fourth voltage line VL4 may include at least one of a line extending in the first direction DR1 or a line extending in the second direction DR2. The line extending in the first direction DR1 and the line extending in the second direction DR2 of the voltage line may be electrically connected to each other even though disposed at (e.g., directly on) different layers among a plurality of insulating layers 10 to 40 illustrated in FIGS. 5B and 5C.

Although the display device DD according to some example embodiments is described with reference to FIG. 2, the display device DD according to the present inventive concepts is not limited thereto. According to the configuration of the pixel circuit, signal lines may be further added or omitted. In addition, an electrical connection relationship between one pixel PX and the signal lines may be also changed.

The plurality of pixels PX may include a plurality of groups that generate light of different colors. For example, the pixels may include red pixels which generate light of a red color, green pixels which generate light of a green color, and blue pixels which generate light of a blue color. A light emitting element of the red pixel, a light emitting element of the green pixel, and a light emitting element of the blue pixel may include emission layers made of different materials.

The pixel circuit may include a plurality of transistors and at least one capacitor. At least one of the scan driver 142 or the data driver 143 may include the plurality of transistors formed through the same process as the pixel circuit.

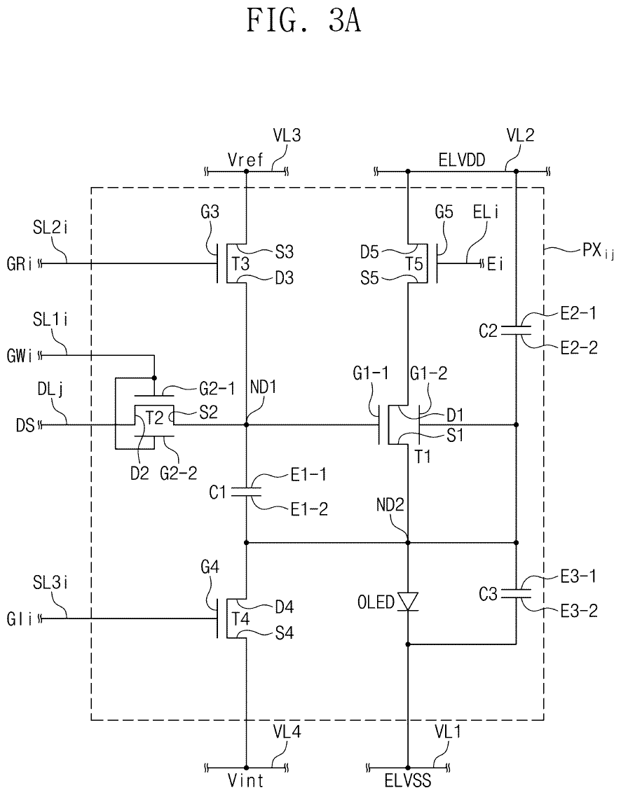

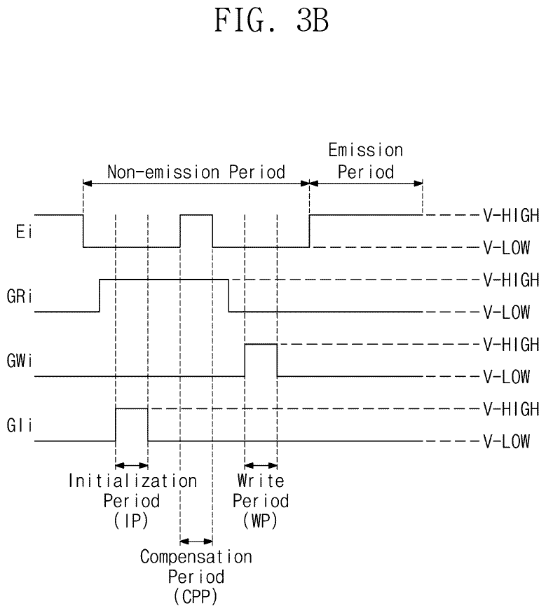

FIG. 3A is an equivalent circuit diagram of a pixel PXij according to some example embodiments of the present inventive concepts. FIG. 3B is a waveform diagram of driving signals for driving the pixel PXij illustrated in FIG. 3A according to some example embodiments of the present inventive concepts.

FIG. 3A representatively illustrates the pixel PXij connected to an i-th scan line SL1i of the first group of scan lines SL11 to SL1n (see FIG. 2) and connected to a j-th data line DLj of the plurality of data lines DL1 to DLm (see FIG. 2). The PXij is connected to an i-th scan line SL2i of a second group of scan lines and connected to an i-th scan line SL3i of a third group of scan lines.

In some example embodiments, including the example embodiments shown in FIG. 3A, a pixel circuit may include first to fifth transistors T1 to T5, a first capacitor C1 to a third capacitor C3, and a light emitting element OLED. In some example embodiments, including the example embodiments shown in FIG. 3A, the first to fifth transistors T1 to T5 may be described as n-type transistors. The first to fifth transistors T1 to T5 may include a semiconductor pattern made of the same material. For example, the first to fifth transistors T1 to T5 may include a metal oxide semiconductor.

However, the first to fifth transistors T1 to T5 are not limited thereto and at least one thereof may be a p-type. For example, the fifth transistor T5 may be a p-type transistor. The fifth transistor T5 may include a semiconductor pattern made of a different material from those of the first to fourth transistors T1 to T4. In some example embodiments of the present inventive concepts, the third capacitor C3 may be omitted.

In some example embodiments, including the example embodiments shown in FIG. 3A, each of the first transistor T1 and the second transistor T2 includes two gates and each of the third to fifth transistors T3 to T5 includes one gate, but example embodiments are not limited thereto. Like the second transistor T2, at least one of the third to fifth transistors T3 to T5 may include two gates.

In some example embodiments, including the example embodiments shown in FIG. 3A, the first transistor T1 may be a driving transistor, and the second transistor T2 may be a switching transistor. A node to which a gate G1-1 (hereinafter referred to as a first upper gate) of the first transistor T1 is connected may be defined as a first node ND1, and a node to which a source S1 of the first transistor T1 is connected may be defined as a second node ND2. The first capacitor C1 is electrically connected between the first node ND1 and the second node ND2, and the light emitting element OLED is electrically connected to the second node ND2.

The light emitting element OLED includes a first electrode electrically connected to the second node ND2, a second electrode electrically connected to a first voltage line VL1 which receives a first power voltage ELVSS, and an emission layer disposed between the first electrode and the second electrode. The light emitting element OLED will be specifically described later.

The first transistor T1 is electrically connected between the second node ND2 and a second voltage line VL2 which receives a second power voltage ELVDD. The first transistor T1 may include the source S1 (hereinafter referred to as a first source) connected to the second node ND2, a drain D1 (hereinafter referred to as a first drain), a channel region (or active region), and the first upper gate G1-1. The first transistor T1 may further include a gate G1-2 (hereinafter referred to as a first lower gate) connected to the second node ND2. The first transistor T1 controls a driving current of the light emitting element OLED on the basis of a charged capacitance of the first capacitor C1.

Here, the first source S1 may include a source region of a semiconductor pattern, or include the source region of the semiconductor pattern and a source electrode connected thereto. In addition, the first drain D1 may include a drain region of the semiconductor pattern, or include the drain region of the semiconductor pattern and a drain electrode connected thereto. The source region and the drain region of the first transistor T1 are disposed on opposite sides of the channel region of the first transistor T1. In an n-type transistor, the source region may be defined as an output region, and the drain region may be defined as an input region. The definitions of the source S1 and the drain D1, described with reference to the first transistor T1, may apply to the second to fifth transistors T2 to T5. The second transistor T2 is electrically connected between the j-th data line DLj and the first node ND1. The second transistor T2 may include a source S2 (hereinafter referred to as a second source) connected to the first node ND1, a drain D2 (hereinafter referred to as a second drain) connected to the j-th data line DLj, a channel region, and a second upper gate G2-1 connected to the i-th scan line SL1i of the first group. The second transistor T2 may further include a gate G2-2 (hereinafter referred to as a second lower gate) connected to the second upper gate G2-1. The second transistor T2 outputs a data voltage. The first capacitor C1 receives the data voltage.

The third transistor T3 is electrically connected between the first node ND1 and a third voltage line VL3 which receives a first voltage Vref. The third transistor T3 may include a drain D3 (hereinafter referred to as a third drain) connected to the first node ND1, a source S3 (hereinafter referred to as a third source) connected to the third voltage line VL3, a channel region, and a third gate G3 connected to the i-th scan line SL2i of the second group.

The fourth transistor T4 is electrically connected between the second node ND2 and a fourth voltage line VL4 which receives a second voltage Vint. The fourth transistor T4 may include a drain D4 (hereinafter referred to as a fourth drain) connected to the second node ND2, a source S4 (hereinafter referred to as a fourth source) connected to the fourth voltage line VL4, a channel region, and a fourth gate G4 connected to the i-th scan line SL3i of the third group.

The fifth transistor T5 is electrically connected between the second voltage line VL2 and the first drain D1 or the first source S1. In some example embodiments, including the example embodiments shown in FIG. 3A, the fifth transistor T5 may include a drain D5 (hereinafter referred to as a fifth drain) connected to the second voltage line VL2, a source S5 (hereinafter referred to as a fifth source) connected to the first drain D1, a channel region, and a fifth gate G5 connected to an i-th emission signal line ELi.

The first capacitor C1 includes a first electrode E1-1 connected to the first node ND1 and a second electrode E1-2 connected to the second node ND2. The second capacitor C2 is electrically connected between the second voltage line VL2 and the second node ND2. The second capacitor C2 includes a first electrode E2-1 connected to the second voltage line VL2 and a second electrode E2-2 connected to the second node ND2. The third capacitor C3 is electrically connected between the first electrode and the second electrode of the light emitting element OLED. The third capacitor C3 may include a first electrode E3-1 connected to the first electrode of the light emitting element OLED, and a second electrode E3-2 connected to the second electrode of the light emitting element OLED.

An operation of the pixel PXij will be described in more detail with reference to FIGS. 3A and 3B. The display device DD (see FIG. 2) displays an image per each frame period. The respective signal lines of the first group of scan lines, the second group of scan lines, the third group of scan lines, and the emission signal lines are sequentially scanned for the frame period. FIG. 3B illustrates a portion of the frame period.

Referring to FIG. 3B, each of signals Ei, GRi, GWi and GIi may have a high level V-HIGH for some periods and have a low level V-LOW for some periods. Each of the n-type first to fifth transistors T1 to T5 described above is turned on when a corresponding control signal has the high level V-HIGH.

For an initialization period IP, the third transistor T3 and the fourth transistor T4 are turned on. The first node ND1 is initiated at the first voltage Vref. The second node ND2 is initiated at the second voltage Vint. The first capacitor C1 is initiated at a difference value between the first voltage Vref and the second voltage Vint. The second capacitor C2 is initiated at a difference value between the second power voltage ELVDD and the second voltage Vint. The third capacitor C3 is initiated at a difference value between the first power voltage ELVSS and the second voltage Vint.

For a compensation period CPP, the third transistor T3 and the fifth transistor T5 are turned on. The first voltage Vref may be supplied to the first node ND1, and the second power voltage ELVDD may be supplied to the first drain D1 of the first transistor T1 so that the first transistor T1 is turned on. When a voltage of the first source S1 of the first transistor T1 reaches a difference between the first voltage Vref and a threshold voltage (Vth) of the first transistor T1, the first transistor T1 may be turned off. A voltage corresponding to the threshold voltage (Vth) of the first transistor T1 may be stored in the first capacitor C1, and the first capacitor C1 may compensate for the threshold voltage (Vth) of the first transistor T1.

For a write period WP, the second transistor T2 is turned on. The second transistor T2 outputs a voltage (or data voltage) corresponding to a data signal DS. As a result, a voltage level corresponding to the data signal DS is charged in the first capacitor C1. The data signal DS in which the threshold voltage of the first transistor T1 is compensated is charged in the first capacitor C1. The threshold voltages of driving transistors may be different for each pixel PX (see FIG. 2), and the pixel PXij illustrated in FIGS. 2 and 3A may supply, to the light emitting element OLED, a current with a magnitude proportional to the data signal DS regardless of a deviation between the threshold voltages of the driving transistors.

Thereafter, for an emission period, the fifth transistor T5 is turned on. The first transistor T1 provides the light emitting element OLED with a current corresponding to a charged capacitance stored in the first capacitor C1. The light emitting element OLED may emit light with a brightness corresponding to the data signal DS.

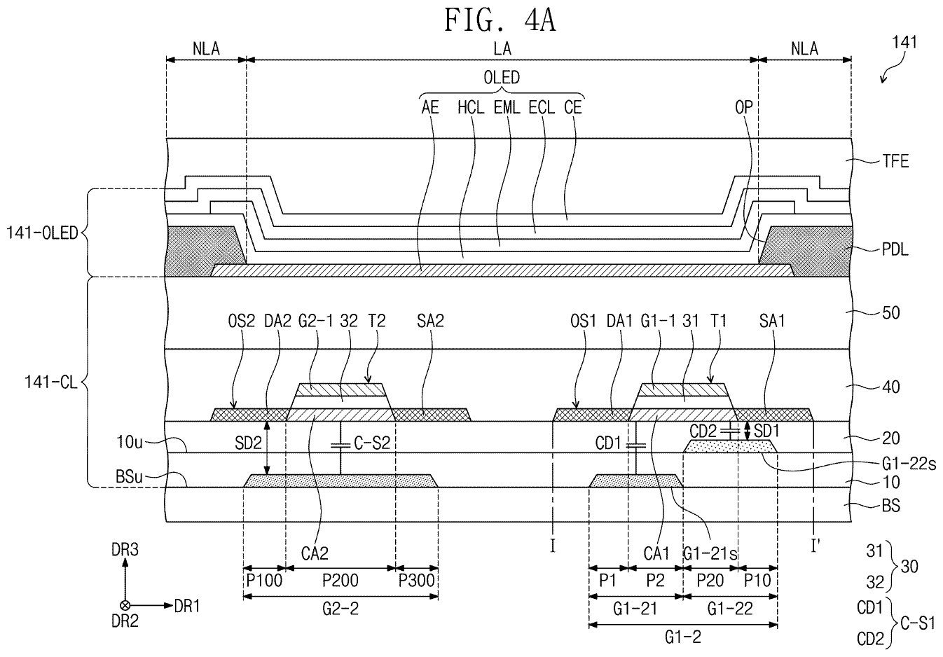

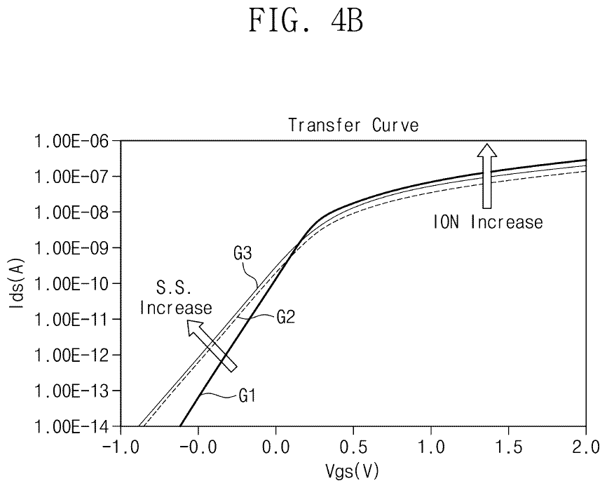

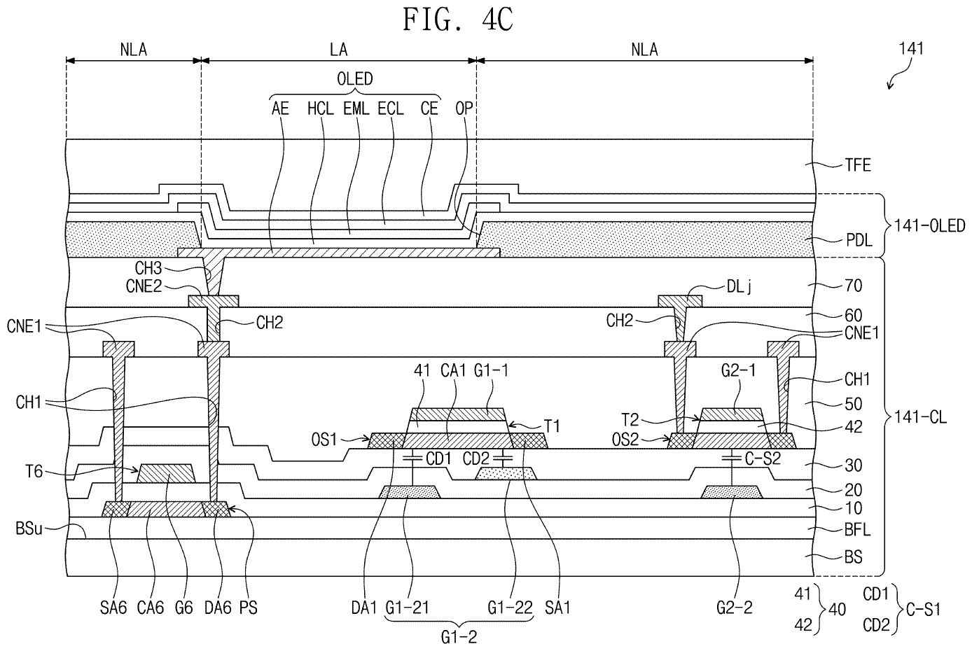

FIG. 4A is a cross-sectional view of a display panel 141 according to some example embodiments of the present inventive concepts. FIG. 4B is a voltage-current graph of a first transistor according to some example embodiments of the present inventive concepts. FIG. 4C is a cross-sectional view of the display panel 141 according to some example embodiments of the present inventive concepts.

Referring to FIG. 4A, the display panel 141 may include a base layer BS, and a circuit element layer 141-CL, a display element layer 141-OLED, and a thin-film encapsulation layer TFE which are disposed on the base layer BS. Although not illustrated, the display panel 141 may further include functional layers such as an anti-reflective layer or a refractive index control layer, which are disposed on the thin-film encapsulation layer TFE.

The circuit element layer 141-CL may include a pixel circuit. The pixel circuit may be disposed in each of the plurality of pixels PX illustrated in FIG. 2. The pixel circuit may include a first transistor T1 and a second transistor T2. The first transistor T1 may be the first transistor T1 in FIG. 3A, and the second transistor T2 may be one of the second to fifth transistors T2 to T5 in FIG. 3A.

The first transistor T1 includes a first oxide semiconductor pattern OS1, a first upper gate G1-1, and a first lower gate G1-2, and the second transistor T2 includes a second oxide semiconductor pattern OS2, a second upper gate G2-1, and a second lower gate G2-2. In some example embodiments, including the example embodiments shown in FIG. 4A, the first lower gate G1-2 includes two gate electrodes disposed at different layers (e.g., directly on different layers, at different distances from a top surface BSu of the base layer BS in a third direction DR3 that is perpendicular to the top surface BSu such that respective bottom surfaces of the two gate electrodes are at different distances from the top surface BSu in the third direction DR3, not overlapping each other or exposed from each other in one or more horizontal directions extending parallel to the top surface BSu, such as the first and second directions DR1 and DR2, any combination thereof, or the like), and the second lower gate G2-2 includes one gate electrode. Gate electrodes disposed at different layers may be directly on different layers. Gate electrodes disposed at different layers may be at different distances from a top surface BSu of the base layer BS in a third direction DR3 that is perpendicular to the top surface BSu. Gate electrodes at different distances from the top surface BSu in the third direction DR3 may have respective closest surfaces to the top surface BSu that are at different distances from the top surface BSu. Gate electrodes disposed at different layers may have respective bottom surfaces at different distances from a top surface BSu of the base layer BS in a third direction DR3 that is perpendicular to the top surface BSu. Gate electrodes disposed at different layers may be not overlapping each other and/or may be exposed from each other in one or more horizontal directions extending parallel to the top surface BSu, such as the first and second directions DR1 and DR2.

The first oxide semiconductor pattern OS1 includes a first input region DA1, a first output region SA1, and a first channel region CA1 disposed between the first input region DA1 and the first output region SA1. The second oxide semiconductor pattern OS2 may be disposed at the same layer (e.g., directly on the same layer) as the first oxide semiconductor pattern OS1. The second oxide semiconductor pattern OS2 includes a second input region DA2, a second output region SA2, and a second channel region CA2 disposed between the second input region DA2 and the second output region SA2.

A portion of the first oxide semiconductor pattern OS1 and the second oxide semiconductor pattern OS2, which are disposed at (e.g., directly on) the same layer, may be formed through the same photolithography process and may include the same semiconductor material. For example, the first oxide semiconductor pattern OS1 and the second oxide semiconductor pattern OS2 may include an indium gallium oxide (IGO) semiconductor, an indium gallium zinc oxide (IGZO) semiconductor, or an indium tin gallium zinc oxide (ITGZO) semiconductor. The constituent materials of the first oxide semiconductor pattern OS1 and the second oxide semiconductor pattern OS2 are not limited thereto. Crystalline states of the first oxide semiconductor pattern OS1 and the second oxide semiconductor pattern OS2 may be the same but are not necessarily limited thereto. Only one of the first oxide semiconductor pattern OS1 or the second oxide semiconductor pattern OS2 may be crystallized through partial crystallization.

The first and second input regions DA1 and DA2 and the first and second output regions SA1 and SA2 are each a reduction region of a metal oxide semiconductor and substantially correspond to a conductive region. The first and second channel regions CA1 and CA2 are each a non-reduction region of the metal oxide semiconductor and substantially correspond to a channel of a transistor.

The base layer BS may include a synthetic resin film. A synthetic resin layer may include a thermosetting resin. In particular, the synthetic resin layer may be a polyimide-based resin layer, and the material thereof is not particularly limited. The synthetic resin layer may include at least one of acrylic-based resin, methacrylic-based resin, polyisoprene, vinyl-based resin, epoxy-based resin, urethane-based resin, cellulose-based resin, siloxane-based resin, polyamide-based resin, or perylene-based resin. In addition, the base layer BS may include a glass substrate, a metal substrate, an organic/inorganic composite material substrate, or the like. The base layer BS may include a first polyimide layer, a second polyimide layer, and an inorganic layer interposed therebetween.

A plurality of insulating layers 10, 20, 30, 40 and 50 are disposed on a top surface BSu of the base layer BS. Each of the plurality of insulating layers 10, 20, 30, 40 and 50 may include an inorganic layer or an organic layer. The plurality of insulating layers 10, 20, 30, 40 and 50 may overlap (e.g., overlap in a third direction DR3 extending perpendicular to the top surface BSu of the base layer BS) the entirety of the top surface BSu of the base layer BS or be partially disposed on only a partial area thereof. A portion of the plurality of insulating layers 10, 20, 30, 40 and 50 may include a plurality of insulating patterns patterned by etching.

The first lower gate G1-2 and the second lower gate G2-2 may be disposed on the base layer BS. Each of the first lower gate G1-2 and the second lower gate G2-2 may include a conductive pattern. For example, each of the first lower gate G1-2 and the second lower gate G2-2 may include a metal pattern. Hereinafter, the first lower gate G1-2 and the second lower gate G2-2 each including a conductive pattern may be defined as a first lower gate electrode G1-2 and a second lower gate electrode G2-2, respectively.

The first lower gate electrode G1-2 may include a plurality of portions disposed at (e.g., directly on) different layers, and thus respective bottom surfaces of the plurality of portions may be at different distances from the top surface BSu of the base layer BS in the third direction DR3 perpendicular to the top surface BSu, exposed from each other in one or more horizontal directions parallel to the top surface BSu, or any combination thereof. As an example, FIG. 4A illustrates the first lower gate electrode G1-2 including two portions. In some example embodiments, including the example embodiments shown in FIG. 4A, the first lower gate electrode G1-2 may include a (1-1)-th gate electrode G1-21 and a (1-2)-th gate electrode G1-22. Hereinafter, the second lower gate electrode G2-2 may be defined as a (2-1)-th gate electrode G2-2.

The (1-1)-th gate electrode G1-21 and the (2-1)-th gate electrode G2-2 are disposed at (e.g., directly on) the same layer, i.e., on (e.g., directly on) the top surface BSu of the base layer BS. The (1-1)-th gate electrode G1-21 and the (2-1)-th gate electrode G2-2 may be formed through the same photolithography process. Thus, the (1-1)-th gate electrode G1-21 and the (2-1)-th gate electrode G2-2 may include the same material and have the same stack structure. In some example embodiments of the present inventive concepts, at least one insulating layer may be further disposed between the top surface BSu of the base layer BS and both the (1-1)-th gate electrode G1-21 and the second lower gate G2-2.

The (1-1)-th gate electrode G1-21 may at least partially overlap the first channel region CA1 on a plane (e.g., may be at least partially overlapped in the third direction DR3 by the first channel region CA1 in the third direction DR3). On a plane, the (1-1)-th gate electrode G1-21 may include a first portion P1 overlapping (e.g., at least partially overlapped in the third direction DR3 by) the first input region DA1, and a second portion P2 overlapping (e.g., at least partially overlapped in the third direction DR3 by) the first channel region CA1. The first and second portions P1 and P2 may be defined by separate portions of a single, unitary piece of material defining (e.g., constituting) the (1-1)-th gate electrode G1-21. As described herein, where an element is described to overlap another element, the element may be at least partially overlapped by the other element. As described herein, where an element is described to overlap another element “on a plane,” the “plane” may be understood to be a plane extending parallel to the top surface BSu of the base layer BS, for example in the first and second directions DR1 and DR2. As described herein, where an element is described to overlap another element “on a plane,” the element may be understood to overlap or be overlapped by the other element in or on a plane extending parallel to the top surface BSu of the base layer BS. The “plane” may be a plane extending parallel to the top surface BSu and, in some example embodiments, may be a plane at least partially defined by the top surface BSu. Where separate relative arrangements, overlaps, and the like with regard to multiple elements are each separately described herein “on a plane,” the separate relative arrangements, overlaps, and the like may collectively be on the same plane.

The (2-1)-th gate electrode G2-2 may at least partially overlap the second channel region CA2 on a plane (e.g., may be at least partially overlapped in the third direction DR3 by the second channel region CA2). On a plane, the (2-1)-th gate electrode G2-2 may include a first portion P100 overlapping (e.g., at least partially overlapped in the third direction DR3 by) the second input region DA2, a second portion P200 overlapping (e.g., at least partially overlapped in the third direction DR3 by) the second channel region CA2, and a third portion P300 overlapping (e.g., at least partially overlapped in the third direction DR3 by) the second output region SA2. The first, second, and third portions P100, P200, and P300 may be defined by separate portions of a single, unitary piece of material defining (e.g., constituting) the (2-1)-th gate electrode G2-2.

Although not illustrated, a buffer layer including at least one inorganic layer may be disposed on (e.g., directly on) the top surface BSu of the base layer BS. Here, the first lower gate G1-2 and the second lower gate G2-2 may be disposed on the buffer layer. The buffer layer may include at least one of aluminum oxide, titanium oxide, silicon oxide, silicon nitride, silicon oxynitride, zirconium oxide, or hafnium oxide. The buffer layer may include an inorganic layer having a multilayer structure.

A first insulating layer 10 which covers the (1-1)-th gate electrode G1-21 and the (2-1)-th gate electrode G2-2 is disposed on (e.g., directly on) the top surface BSu of the base layer BS. The first insulating layer 10 may include at least one of aluminum oxide, titanium oxide, silicon oxide, silicon nitride, silicon oxynitride, zirconium oxide, or hafnium oxide. The first insulating layer 10 may include an inorganic layer having a multilayer structure.

The (1-2)-th gate electrode G1-22 is disposed on (e.g., directly on) the first insulating layer 10 (e.g., directly on a top surface 10u of the first insulating layer 10). The (1-2)-th gate electrode G1-22 may be formed through a different photolithography process from the (1-1)-th gate electrode G1-21. However, the (1-2)-th gate electrode G1-22 may include the same material as the (1-1)-th gate electrode G1-21. The (1-2)-th gate electrode G1-22 may at least partially overlap (e.g., may be at least partially overlapped in the third direction DR3 by) the first channel region CA1 on a plane. On a plane, the (1-2)-th gate electrode G1-22 may include a first portion P10 overlapping (e.g., at least partially overlapped in the third direction DR3 by) the first output region SA1, and a second portion P20 overlapping (e.g., at least partially overlapped in the third direction DR3 by) the first channel region CA1. Accordingly, it will be understood that the first upper gate G1-1 may be above the first channel region CA1 while the (1-1)-th gate electrode G1-21 and the (1-2)-th gate electrode G1-22 may each be below the first channel region CA1 and at least partially overlapped by the first channel region CA1 in the third direction DR3, such that the first channel region CA1 may be understood to be between the first upper gate G1-1 and the first lower gate G1-2 (comprising both the (1-1)-th gate electrode G1-21 and the (1-2)-th gate electrode G1-22) in the third direction DR3. The first and second portions P10 and P20 may be defined by separate portions of a single, unitary piece of material defining (e.g., constituting) the (1-2)-th gate electrode G1-22.

As shown, the (1-1)-th gate electrode G1-21 and the (1-2)-th gate electrode G1-22 may be at different layers. For example, the (1-1)-th gate electrode G1-21 and the (1-2)-th gate electrode G1-22 may be at different distances from a top surface BSu of the base layer BS in a third direction DR3 that is perpendicular to the top surface BSu. For example, the (1-1)-th gate electrode G1-21 and the (1-2)-th gate electrode G1-22 may be at different layers such that one of the (1-1)-th gate electrode G1-21 or the (1-2)-th gate electrode G1-22 is closer to the top surface BSu in the third direction DR3 (which extends perpendicular to the top surface BSu) than the other one of the (1-1)-th gate electrode G1-21 or the (1-2)-th gate electrode G1-22 in the third direction DR3. For example, the (1-1)-th gate electrode G1-21 may have a proximate surface G1-21s (e.g., a bottom surface) that is a closest surface of the (1-1)-th gate electrode G1-21 to the top surface BSu in the third direction DR3 and which may be on or directly on the top surface BSu, the (1-2)-th gate electrode G1-22 may have a proximate surface G1-22s (e.g., a bottom surface) that is a closest surface of the (1-2)-th gate electrode G1-22 to the top surface BSu in the third direction DR3, and the proximate surface G1-21s of the (1-1)-th gate electrode G1-21 may be closer than the proximate surface G1-22s of the (1-2)-th gate electrode G1-22 to the top surface BSu in the third direction DR3. For example, the (1-1)-th gate electrode G1-21 and the (1-2)-th gate electrode G1-22 may not overlap each other or may be exposed from each other in one or more horizontal directions extending parallel to the top surface BSu, such one or more horizontal directions including the first and second directions DR1 and DR2. It will be understood that the third direction DR3 may be referred to interchangeably herein as a vertical direction extending perpendicular to the top surface BSu, and the first and second directions DR1 and DR2 may each be referred to interchangeably herein as a horizontal direction extending parallel to the top surface BSu, where the first and second directions DR1 and DR2 may cross each other (e.g., may extend perpendicular to each other).

A second insulating layer 20 which covers the (1-2)-th gate electrode G1-22 is disposed on a top surface 10u of the first insulating layer 10, for example such that the first insulating layer 10 is between the (1-1)-th gate electrode G1-21 and the second insulating layer 20 in the third direction DR3 and, in some example embodiments, the first insulating layer 10 is between the (1-1)-th gate electrode G1-21 and the (1-2)-th gate electrode G1-22 in the third direction DR3. The second insulating layer 20 may include at least one of aluminum oxide, titanium oxide, silicon oxide, silicon nitride, silicon oxynitride, zirconium oxide, or hafnium oxide. The second insulating layer 20 may include an inorganic layer having a multilayer structure.

The first oxide semiconductor pattern OS1 and the second oxide semiconductor pattern OS2 are disposed on the second insulating layer 20. A (3-1) insulating pattern 31 is disposed on the first channel region CA1, and a (3-2) insulating pattern 32 is disposed on the second channel region CA2. The (3-1) insulating pattern 31 and the (3-2) insulating pattern 32 may be different portions of a third insulating layer 30. The third insulating layer 30 which covers the first oxide semiconductor pattern OS1 and the second oxide semiconductor pattern OS2 may be provided on the second insulating layer 20, and then the third insulating layer 30 may be patterned through a photolithography process. The third insulating layer 30 may include at least one of aluminum oxide, titanium oxide, silicon oxide, silicon nitride, silicon oxynitride, zirconium oxide, or hafnium oxide. Each of the (3-1) insulating pattern 31 and the (3-2) insulating pattern 32 may include an inorganic layer having a multilayer structure.

The first upper gate G1-1 is disposed on (e.g., directly on) the (3-1) insulating pattern 31, and the second upper gate G2-1 is disposed on (e.g., directly on) the (3-2) insulating pattern 32. Each of the first upper gate G1-1 and the second upper gate G2-1 may include a conductive pattern. For example, each of the first upper gate G1-1 and the second upper gate G2-1 may include a metal pattern. Hereinafter, the first upper gate G1-1 and the second upper gate G2-1 each including a conductive pattern may be defined as a first upper gate electrode G1-1 and a second upper gate electrode G2-1, respectively. Hereinafter, the first upper gate electrode G1-1 may be defined as a first gate electrode G1-1, and the second upper gate electrode G2-1 may be defined as a second gate electrode G2-1. The first gate electrode G1-1 may be understood to be above the first channel region CA1 and at least partially overlapping the first channel region CA1 in the third direction DR3. The second gate electrode G2-1 may be understood to be above the second channel region CA2 and at least partially overlapping the second channel region CA2 in the third direction DR3.

A fourth insulating layer 40 which covers the first gate electrode G1-1 and the second gate electrode G2-1 is disposed on the second insulating layer 20. The fourth insulating layer 40 may include an organic or inorganic layer having a single-layer or multilayer structure. A fifth insulating layer 50 is disposed on the fourth insulating layer 40. The fifth insulating layer 50 may include an organic layer having a single-layer or multilayer structure.

A light emitting element OLED is disposed on the fifth insulating layer 50. A first electrode AE of the light emitting element OLED is disposed on the fifth insulating layer 50. The first electrode AE may be an anode. The first electrode AE is electrically connected to the first output region SA1. The first electrode AE may be directly connected to the first output region SA1 through a contact hole passing through the fourth insulating layer 40 and the fifth insulating layer 50, or be connected to the first output region SA1 through a connection electrode disposed between the fourth insulating layer 40 and the fifth insulating layer 50.

A pixel defining film PDL is disposed on the fifth insulating layer 50. An opening portion OP of the pixel defining film PDL exposes at least a portion of the first electrode AE. The opening portion OP of the pixel defining film PDL may define an emission area LA. For example, the plurality of pixels PX (see FIG. 2) may be disposed according to a certain rule on a plane of the display panel 141 (e.g., on or in a plane extending in the first and second directions DR1 and DR2 and parallel to the top surface BSu of the base layer BS). An area (e.g., an area on or in a plane extending in the first and second directions DR1 and DR2 and parallel to the top surface BSu of the base layer BS) in which the plurality of pixels PX are disposed may be defined as a display area, and the display area may include a plurality of emission areas LA and a non-emission area NLA adjacent to the emission areas LA. The non-emission area NLA may surround the emission area LA (e.g., surround the emission area LA on or in a plane extending in the first and second directions DR1 and DR2 and parallel to the top surface BSu of the base layer BS).

A hole control layer HCL may be disposed, in common, in the emission area LA and the non-emission area NLA, for example such that separate portions of a single, unitary piece of material comprising the hole control layer HCL are in the emission area LA and the non-emission area NLA. A common layer such as the hole control layer HCL may be provided, in common, in the plurality of pixels PX, for example such that separate portions of a single, unitary piece of material comprising the hole control layer HCL are in separate, respective pixels of the plurality of pixels PX. The hole control layer HCL may include a hole transport layer and a hole injection layer.

An emission layer EML is disposed on the hole control layer HCL. The emission layer EML may not be disposed on a portion of the pixel defining film PDL and thus may expose the portion of the pixel defining film PDL in the third direction DR3. The emission layer EML may be disposed only in an area corresponding to the opening portion OP. The emission layer EML may be divided to be disposed in each of the plurality of pixels PX illustrated in FIG. 2.

In some example embodiments, including the example embodiments shown in FIG. 4A, the emission layer EML which is patterned is illustrated as an example, but the emission layer EML may be disposed, in common, in the plurality of pixels PX. The emission layer EML disposed in common may generate white light or blue light. In addition, the emission layer EML may have a multilayer structure.

An electron control layer ECL is disposed on the emission layer EML. The electron control layer ECL may include an electron transport layer and an electron injection layer. A second electrode CE is disposed on the electron control layer ECL. The electron control layer ECL and the second electrode CE are disposed, in common, in the plurality of pixels PX.

The thin-film encapsulation layer TFE is disposed on the second electrode CE. The thin-film encapsulation layer TFE is disposed, in common, in the plurality of pixels PX illustrated in FIG. 2. In some example embodiments, including the example embodiments shown in FIG. 4A, the thin-film encapsulation layer TFE directly covers the second electrode CE (e.g., is in direct contact with the second electrode CE). In some example embodiments of the present inventive concepts, a capping layer which directly covers the second electrode CE may be further disposed. In some example embodiments of the present inventive concepts, a stack structure of the light emitting element OLED may include a structure in which the structure illustrated in FIG. 4A is inverted.

The thin-film encapsulation layer TFE at least includes an inorganic layer or an organic layer. In some example embodiments of the present inventive concepts, the thin-film encapsulation layer TFE may include two inorganic layers and an organic layer interposed therebetween. In some example embodiments of the present inventive concepts, the thin-film encapsulation layer may include a plurality of inorganic layers and a plurality of organic layers, which are alternately stacked.

The first lower gate electrode G1-2 (also referred to herein as the first lower gate G1-2) may define the first channel region CA1 and a first parasitic capacitor C-S1. In some example embodiments, the (1-1)-th gate electrode G1-21 and the (1-2)-th gate electrode G1-22 may each be electrically connected to the first output region SA1. The first parasitic capacitor C-S1 is defined as a sum of a (1-1)-th parasitic capacitor CD1, defined by the (1-1)-th gate electrode G1-21 and the first channel region CA1, and a (1-2)-th parasitic capacitor CD2 defined by the (1-2)-th gate electrode G1-22 and the first channel region CA1. Accordingly, the first parasitic capacitor C-S1 may define a capacitor electrically connected between the first lower gate electrode G1-2 and the first channel region CA1.

A capacitance of the (1-1)-th parasitic capacitor CD1 may be determined by an overlapping area between the second portion P2 of the (1-1)-th gate electrode G1-21 and the first channel region CA1 (e.g., between respective portions thereof overlapping each other in the third direction DR3 extending perpendicular to the top surface BSu, where the overlapping area may be an area in or on a plane extending parallel to the top surface BSu). A capacitance of the (1-2)-th parasitic capacitor CD2 may be determined by an overlapping area between the second portion P2 of the (1-2)-th gate electrode G1-22 and the first channel region CA1 (e.g., between respective portions thereof overlapping each other in the third direction DR3 extending perpendicular to the top surface BSu, where the overlapping area may be an area in or on a plane extending parallel to the top surface BSu). For example, as shown in FIG. 4A, the capacitance of the (1-1)-th parasitic capacitor CD1 may be determined by an overlapping area that is an area, in or on a plane extending parallel to the top surface BSu, of an overlap between respective portions of the (1-1)-th gate electrode G1-21 and the first channel region CA1 in the third direction DR3, and the capacitance of the (1-2)-th parasitic capacitor CD2 may be determined by an overlapping area that is an area, in or on a plane extending parallel to the top surface BSu, of an overlap between respective portions of the (1-2)-th gate electrode G1-22 and the first channel region CA1 in the third direction DR3.

When the overlapping area between the second portion P2 of the (1-1)-th gate electrode G1-21 and the first channel region CA1 is increased, the capacitance of the (1-1)-th parasitic capacitor CD1 is increased, and when the overlapping area between the second portion P20 of the (1-2)-th gate electrode G1-22 and the first channel region CA1 is decreased, the capacitance of the (1-2)-th parasitic capacitor CD2 is decreased. Here, a capacitance of the first parasitic capacitor C-S1 is decreased. The overlapping area between the second portion P20 of the (1-2)-th gate electrode G1-22 and the first channel region CA1 more significantly affects an increase and decrease in capacitance of the first parasitic capacitor C-S1 than the overlapping area between the second portion P2 of the (1-1)-th gate electrode G1-21 and the first channel region CA1 does. This is because the (1-2)-th gate electrode G1-22 is more adjacent to (e.g., closer in the third direction DR3 to) the first channel region CA1 than the (1-1)-th gate electrode G1-21 is.

When the overlapping areas between the second portions P2 and P20 and the first channel region CA1 are increased, the capacitance of the first parasitic capacitor C-S1 is increased. The overlapping area between the second portion P2 of the (1-1)-th gate electrode G1-21 and the first channel region CA1 and the overlapping area between the second portion P20 of the (1-2)-th gate electrode G1-22 and the first channel region CA1 are the same, the capacitance of the (1-2)-th parasitic capacitor CD2 is greater than the capacitance of (1-1)-th parasitic capacitor CD1. This is because the (1-2)-th gate electrode G1-22 is more adjacent to (e.g., closer in the third direction DR3 to) the first channel region CA1 than the (1-1)-th gate electrode G1-21 is.

The (2-1)-th gate electrode G2-2 may define the second channel region CA2 and a second parasitic capacitor C-S2. A capacitance of the second parasitic capacitor C-S2 is less than the capacitance of the first parasitic capacitor C-S1. The (2-1)-th gate electrode G2-2 is disposed on a lower side of the first insulating layer 10 (e.g., between the first insulating layer 10 and the top surface BSu of the base layer BS) and defines the second parasitic capacitor C-S2 having a relatively low capacitance. For example, the second upper gate electrode G2-1 may be above the second channel region CA2 and overlapping the second channel region CA2 in the third direction DR2, and the (2-1)-th gate electrode G2-2 may be below the second channel region CA2 and at least partially overlapped by the second channel region CA2 in the third direction DR3. In some example embodiments, a first separation distance SD1 in the third direction DR3 between the first channel region CA1 and the (1-2)-th gate electrode G1-2 may be smaller than a second separation distance SD2 in the third direction DR3 between the second channel region CA2 and the (2-1)-th gate electrode G2-2. If the (2-1)-th gate electrode G2-2 is disposed on an upper side of the first insulating layer 10 and disposed at (e.g., directly on) the same layer as the (1-2)-th gate electrode G1-22, the capacitance of the second parasitic capacitor C-S2 is increased. However, when the capacitance of the second parasitic capacitor C-S2 is increased, a very large load is applied to the second transistor T2 having a double-gate structure to adversely affect an operation of a switching transistor.

FIG. 4B illustrates first to third graphs G1, G2 and G3. The first to third graphs G1, G2 and G3 are voltage (Vgs)-current (Ids) curves of driving transistors. A threshold voltage (Vth) of the voltage (Vgs)-current (Ids) curves may be about 0.64 V.

The third graph G3 is the voltage (Vgs)-current (Ids) curve of the first transistor T1 in FIG. 4A. In contrast, the driving transistors having the voltage (Vgs)-current (Ids) curves in the first and second graphs G1 and G2 have partially different structures from the first transistor T1 in FIG. 4A. Hereinafter, the driving transistors having the voltage (Vgs)-current (Ids) curves in the first and second graphs G1 and G2 are described in comparison with the first transistor T1 in FIG. 4A.

In the driving transistor of the first graph G1, unlike the first transistor T1 in FIG. 4A, a first lower gate G1-2 includes only a (1-1)-th gate electrode G1-21 without a (1-2)-th gate electrode G1-22. However, the (1-1)-th gate electrode G1-21 completely overlaps (e.g., is overlapped in the third direction DR3 by an entirety of) a first channel region CA1. This is the same or substantially the same as a case in which a (2-1)-th gate electrode G2-2 completely overlaps (e.g., is overlapped in the third direction DR3 by an entirety of) a second channel region CA2. The (1-1)-th gate electrode G1-21 may include three portions like the (2-1)-th gate electrode G2-2.

In the driving transistor of the second graph G2, unlike the first transistor T1 in FIG. 4A, a first lower gate G1-2 includes only a (1-2)-th gate electrode G1-22 without a (1-1)-th gate electrode G1-21. Here, the (1-2)-th gate electrode G1-22 completely overlaps (e.g., is overlapped in the third direction DR3 by an entirety of) a first channel region CA1. The (1-2)-th gate electrode G1-22 may include three portions like the (2-1)-th gate electrode G2-2.

According to the first graph G1, a slope of the graph is large in a subthreshold region. That is, a low-grayscale driving voltage range of the transistor is relatively narrow. However, a driving current Ion (on current) is relatively high in a saturation region.

According to the second graph G2, a slope of the graph is small in the subthreshold region. That is, a low-grayscale driving voltage range of the transistor is relatively broad. However, a driving current Ion (on current) is relatively low in the saturation region.

According to the third graph G3, a slope of the graph in the subthreshold region is similar to that of the second graph G2. That is, a low-grayscale driving voltage range of the transistor is relatively broad. A subthreshold swing may be increased to increase the low-grayscale driving voltage range of the first transistor, and as a result, low-grayscale display quality may be improved. Accordingly, as shown by the third graph G3 in FIG. 4B, a display device (e.g., display device 11) may exhibit improved low-grayscale display quality, for example based on exhibiting an increased subthreshold swing, a low-grayscale driving voltage range, or the like based on the first transistor T1 including first upper gate electrode G1-1 above the first channel region CA1 and a first lower gate G1-2 below the first channel region CA1 where the first lower gate G1-2 includes both the (1-1)-th gate electrode G1-21 and the (1-2)-th gate electrode G1-22 below the first channel region CA1 and at different layers such that one of the (1-1)-th gate electrode G1-21 or the (1-2)-th gate electrode G1-22 is closer to the top surface BSu of the base layer BS than another one of the (1-1)-th gate electrode G1-21 or the (1-2)-th gate electrode G1-22 in the third direction DR3.

In addition, according to the third graph G3, a driving current Ion (on current) in the saturation region is lower than that of the first graph G1 but higher than that of the second graph G2. Compared to the second graph G2, the third graph G3 shows that the driving current Ion (on current) of the first transistor is increased at the same voltage Vgs. Compared to the second graph G2, the third graph G3 shows that the driving voltage range (or a data swing range (DSR)) is decreased in the saturation region, and as a result, the power consumption may be reduced. As a result, for the driving transistor having the characteristics of the third graph G3, the low-grayscale driving voltage range is broad and the driving current is relatively high, based on the first transistor T1 including first upper gate electrode G1-1 above the first channel region CA1 and a first lower gate G1-2 below the first channel region CA1 where the first lower gate G1-2 includes both the (1-1)-th gate electrode G1-21 and the (1-2)-th gate electrode G1-22 below the first channel region CA1 and at different layers such that one of the (1-1)-th gate electrode G1-21 or the (1-2)-th gate electrode G1-22 is closer to the top surface BSu of the base layer BS than another one of the (1-1)-th gate electrode G1-21 or the (1-2)-th gate electrode G1-22 in the third direction DR3. It may be also known that the third graph G3 shows the broader driving voltage range and the higher driving current than the second graph G2.

FIG. 4C illustrates a cross-sectional view of a display panel 141 different from the display panel 141 in FIG. 4A. FIG. 4C differs from FIG. 4A in terms of a stacking relationship between an insulating layer and patterns, and FIG. 4C further illustrates a sixth transistor T6 compared to FIG. 4A.

A pixel of the display panel 141 according to some example embodiments, including the example embodiments shown in FIG. 4C, may further include the sixth transistor T6 compared to the pixel PXij illustrated in FIG. 3A. On the basis of the equivalent circuit in FIG. 3A, the sixth transistor T6 may be disposed between the second node ND2 and the light emitting element OLED. Here, the fourth drain D4 of the fourth transistor T4 in FIG. 3A is connected to an output terminal of the sixth transistor T6 and an anode of the light emitting element OLED, not to the second node ND2.

The sixth transistor T6 may include a semiconductor pattern made of a different material from that of at least a portion of the first to fifth transistors T1 to T5 in FIG. 3A. The sixth transistor T6 may be a different type of transistor from at least a portion of the first to fifth transistors T1 to T5 in FIG. 3A. In some example embodiments, including the example embodiments shown in FIG. 4C, the sixth transistor T6 may be a p-type transistor.

Hereinafter, differences between the display panel 141 in FIG. 4A and the display panel 141 in FIG. 4C are mainly described. Despite the differences between the display panel 141 in FIG. 4A and the display panel 141 in FIG. 4C, the characteristics of the first transistor T1 described with reference to FIGS. 4A and 4B may apply to the example embodiments shown in FIG. 4C.

Referring to FIG. 4C, a silicon semiconductor pattern PS is disposed on a buffer layer BFL. In the silicon semiconductor pattern PS, a silicon semiconductor may include amorphous silicon, polycrystalline silicon, or the like. For example, the silicon semiconductor pattern PS may include polysilicon crystallized at a low temperature (hereinafter referred to as crystalline polysilicon).

The silicon semiconductor pattern PS may have different electrical properties according to whether or not the silicon semiconductor pattern PS is doped. The silicon semiconductor pattern PS includes an input region SA6 (hereinafter referred to as a sixth input region), an output region DA6 (hereinafter referred to as a sixth output region), and a channel region CA6 (hereinafter referred to as a sixth channel region) disposed between the sixth input region SA6 and the sixth output region DA6. The sixth input region SA6 and the sixth output region DA6 correspond to a source and a drain of the sixth transistor T6, respectively. Although not separately illustrated, the fifth transistor T5 described with reference to FIG. 3A may also include a semiconductor pattern formed through the same process and including the same material as the silicon semiconductor pattern PS of the sixth transistor T6.

A gate electrode G6 (hereinafter referred to as a sixth gate electrode) is disposed on the sixth channel region CA6. The sixth gate electrode G6 may be formed through the same process and include the same metal as a (1-1)-th gate electrode G1-21 and a (2-1)-th gate electrode G2-2.

A first transistor T1 and a second transistor T2 disposed on a first insulating layer 10 in FIG. 4C may be the same or substantially the same as the first transistor T1 and the second transistor T2 disposed on the base layer BS in FIG. 4A. A fifth insulating layer 50 which covers the first transistor T1 and the second transistor T2 is disposed on a third insulating layer 30. The fifth insulating layer 50 may include an organic layer having a single-layer or multilayer structure. In the functional aspect, a fourth insulating layer 40 and the fifth insulating layer 50 in FIG. 4C correspond to the third insulating layer 30 and the fourth insulating layer 40 in FIG. 4A.

At least one first connection electrode CNE1 may be disposed on the fifth insulating layer 50. Four first connection electrodes CNE1 are illustrated as an example. The four first connection electrodes CNE1 are respectively connected to the sixth input region SA6, the sixth output region DA6, a second input region DA2, and a second output region SA2 through first contact holes CH1 passing through (e.g., at least partially defined by respective inner surfaces of) corresponding insulating layers.

A sixth insulating layer 60 is disposed on the fifth insulating layer 50. The sixth insulating layer 60 may include an organic layer. At least one second connection electrode CNE2 may be disposed on the sixth insulating layer 60. The second connection electrode CNE2 may be connected to the sixth output region DA6 through a second contact hole CH2 passing through the sixth insulating layer 60. A data line DLj may be disposed on the sixth insulating layer 60. The data line DLj may be connected to the second input region DA2 through the second contact hole CH2 passing through the sixth insulating layer 60.

A seventh insulating layer 70 is disposed on the sixth insulating layer 60. The seventh insulating layer 70 may include an organic layer. In the functional aspect, the seventh insulating layer 70 corresponds to the fifth insulating layer 50 in FIG. 4A. A first electrode AE may be connected to the second connection electrode CNE2 through a third contact hole CH3 passing through the seventh insulating layer 70.

FIG. 5A is a plan view of a first transistor T1 according to some example embodiments of the present inventive concepts. FIG. 5B is a cross-sectional view of the first transistor T1 along line II-II′ in FIG. 5A according to some example embodiments of the present inventive concepts. FIG. 5C is a cross-sectional view of a second transistor T2 according to some example embodiments of the present inventive concepts.

Hereinafter, FIG. 4A is referenced together to describe the first transistor T1 and the second transistor T2. A cross-section of the first transistor T1 corresponding to line I-I′ in FIG. 5A is the same as that illustrated in FIG. 4A.

As illustrated in FIGS. 4A, 5A, and 5B, a (1-1)-th gate electrode G1-21 and a (1-2)-th gate electrode G1-22 are arranged in the first direction DR1 on a first oxide semiconductor pattern OS1. On the first oxide semiconductor pattern OS1, the (1-1)-th gate electrode G1-21 is disposed more adjacent to a first input region DA1 than a first output region SA1, and the (1-2)-th gate electrode G1-22 is disposed more adjacent to the first output region SA1 than the first input region DA1. For example, the (1-1)-th gate electrode G1-21 may be closer to the first input region DA1 than the first output region SA1 in a horizontal direction (e.g., at least one of the first direction DR1 or the second direction DR2) extending parallel to the top surface BSu of the base layer BS, and the (1-2)-th gate electrode G1-22 is disposed closer to the first output region SA1 than the first input region DA1 in the horizontal direction. As shown, the (1-1)-th gate electrode G1-21 may be disposed more adjacent to the base layer BS than the (1-2)-th gate electrode G1-22 is, such that the (1-1)-th gate electrode G1-21 may be closer than the (1-2)-th gate electrode G1-22 to the base layer BS in the third direction DR3.

The (1-1)-th gate electrode G1-21 may include a first portion P1, a second portion P2, and a third portion P3 which are divided in the first direction DR1. The first portion P1 at least overlaps a first input region DA1 on a plane (e.g., is at least partially overlapped in the third direction DR3 by the first input region DA1), and the second portion P2 at least overlaps a first channel region CA1 on a plane (e.g., is at least partially overlapped in the third direction DR3 by the first channel region CA1). The second portion P2 is disposed more adjacent to the first output region SA1 than the first portion P1 is. For example, the second portion P2 may be closer than the first portion P1 to the first output region SA1 in a horizontal direction (e.g., at least one of the first direction DR1 or the second direction DR2) extending parallel to the top surface BSu of the base layer BS. In another example, the second portion P2 may be at least partially between the first output region SA1 and the first portion P1 in the horizontal direction. The third portion P3 extends from the second portion P2 and overlaps a first connection electrode CNE1 to be described later. The third portion P3 does not overlap the first oxide semiconductor pattern OS1 (e.g., is exposed from the first oxide semiconductor pattern OS1 in the third direction DR3). The first, second, and third portions P1, P2, and P3 may be defined by separate portions of a single, unitary piece of material defining (e.g., constituting) the (1-1)-th gate electrode G1-21.

The (1-2)-th gate electrode G1-22 may include a first portion P10, a second portion P20, and a third portion P30 which are divided in the first direction DR1. The first portion P10 at least overlaps the first output region SA1 on a plane (e.g., is at least partially overlapped in the third direction DR3 by the first output region SA1), and the second portion P20 at least overlaps the first channel region CA1 on a plane (e.g., is at least partially overlapped in the third direction DR3 by the first channel region CA1). The second portion P20 is disposed more adjacent to the first input region DA1 than the first portion P10 is. For example, the second portion P20 may be closer than the first portion P10 to the first input region DA1 in a horizontal direction (e.g., at least one of the first direction DR1 or the second direction DR2) extending parallel to the top surface BSu of the base layer BS. The third portion P30 extends from the first portion P10 and overlaps the first connection electrode CNE1 to be described later. The third portion P30 does not overlap the first oxide semiconductor pattern OS1 (e.g., is exposed from the first oxide semiconductor pattern OS1 in the third direction DR3). The first, second, and third portions P10, P20, and P30 may be defined by separate portions of a single, unitary piece of material defining (e.g., constituting) the (1-2)-th gate electrode G1-22.

As illustrated in FIG. 5A, the first oxide semiconductor pattern OS1 may be disposed between the third portion P3 of the (1-1)-th gate electrode G1-21 and the third portion P30 of the (1-2)-th gate electrode G1-22 in the second direction DR2 (which may extend parallel to the top surface BSu of the base layer BS).

As illustrated in FIGS. 5A and 5B, the first connection electrode CNE1 may be arranged to overlap the first output region SA1 (e.g., overlap in the third direction DR3). The planar shape of the first connection electrode CNE1 is not particularly limited.

The first connection electrode CNE1 electrically connects the first output region SA1, the (1-1)-th gate electrode G1-21, and the (1-2)-th gate electrode G1-22. The first connection electrode CNE1 is connected to the (1-1)-th gate electrode G1-21 through a first contact hole CH1. The first contact hole CH1 may pass through (e.g., may be at least partially defined by respective inner surfaces of) first, second and fourth insulating layers 10, 20 and 40 as in FIG. 5B. The first connection electrode CNE1 is connected to the (1-2)-th gate electrode G1-22 through a second contact hole CH2. The second contact hole CH2 may pass through (e.g., may be at least partially defined by respective inner surfaces of) the second and fourth insulating layers 20 and 40 as in FIG. 5B. The first connection electrode CNE1 is connected to the first output region SA1 through a third contact hole CH3. The third contact hole CH3 may pass through (e.g., may be at least partially defined by one or more inner surfaces of) the fourth insulating layer 40 as in FIG. 5B. A portion of the first connection electrode CNE1 is disposed on the fourth insulating layer 40. The first contact hole CH1 and the second contact hole CH2 are arranged to be spaced apart from a first gate electrode G1-1 (also referred to as a first upper gate) and the first oxide semiconductor pattern OS1 (e.g., spaced apart therefrom in one or more horizontal directions extending parallel to the top surface BSu of the base layer BS).

FIG. 5C illustrates a cross-section of the second transistor T2 on the basis of a different cutting line from that in FIG. 4A. Referring to FIG. 5C, a second gate electrode G2-1 and a (2-1)-th gate electrode G2-2 may be electrically connected by a second connection electrode CNE2. The second connection electrode CNE2 may be connected to the (2-1)-th gate electrode G2-2 through a fourth contact hole CH4 passing through the first, second and fourth insulating layers 10, 20 and 40, and be connected to the second gate electrode G2-1 through a fifth contact hole CH5 passing through the fourth insulating layer 40. The second connection electrode CNE2 may be formed through the same photolithography process as the first connection electrode CNE1 in FIG. 5B.

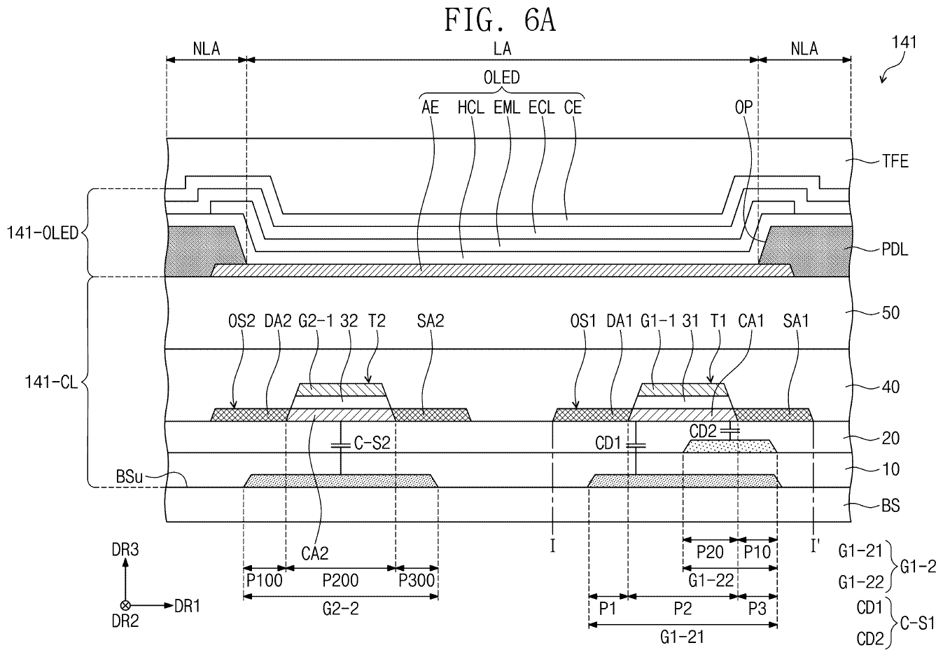

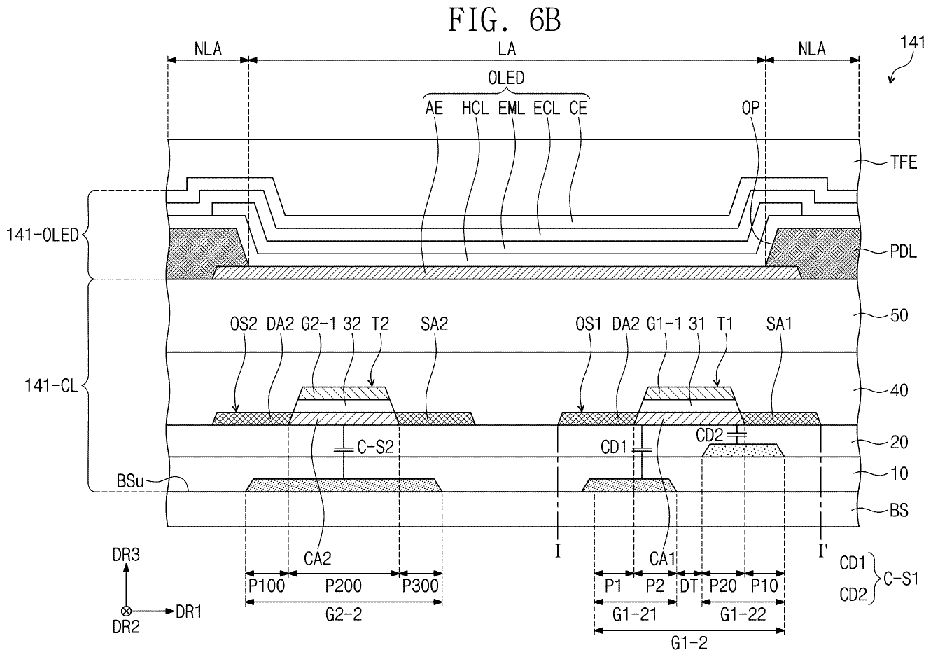

FIGS. 6A and 6B are each a cross-sectional view of a display panel 141 according to some example embodiments of the present inventive concepts. Hereinafter, FIGS. 4A to 5C are referenced for details of the same components as the components described with reference to FIGS. 4A to 5C.

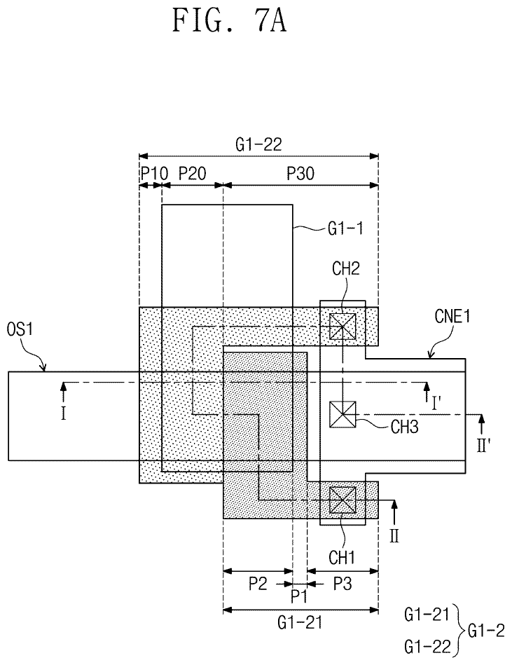

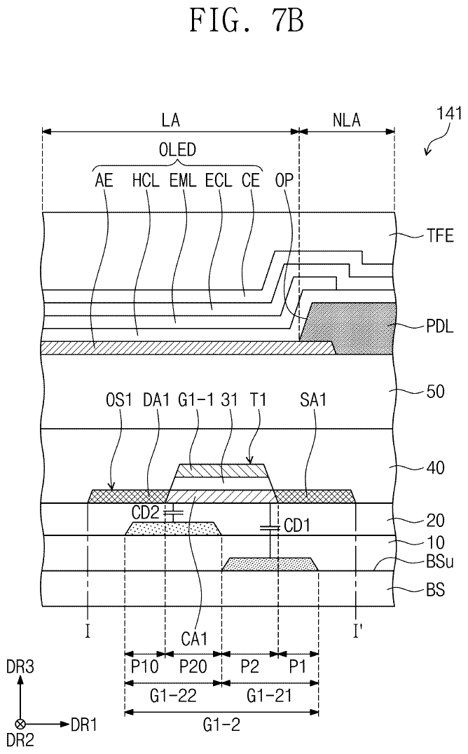

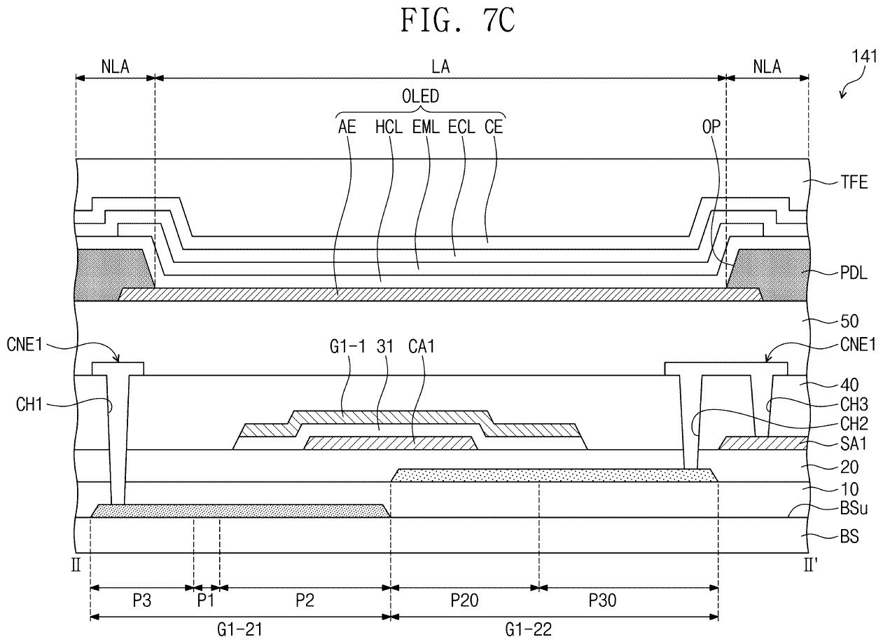

Referring to FIG. 6A, on a plane (e.g., in or on a plane extending parallel to the top surface BSu of the base layer BS), a (1-1)-th gate electrode G1-21 may include a first portion P1 overlapping a first input region DA1 (e.g., at least partially overlapped in the third direction DR3 by the first input region DA1), a second portion P2 overlapping a first channel region CA1 (e.g., at least partially overlapped in the third direction DR3 by the first channel region CA1), and a third portion P3 overlapping a first output region SA1 (e.g., at least partially overlapped in the third direction DR3 by the first output region SA1). The second portion P2 and the third portion P3 of the (1-1)-th gate electrode G1-21 may overlap a (1-2)-th gate electrode G1-22 (e.g., may be at least partially overlapped in the third direction DR3 by the (1-2)-th gate electrode G1-22). Compared to FIG. 4A, a capacitance of a (1-2)-th parasitic capacitor CD2 may be the same, but a capacitance of a (1-1)-th parasitic capacitor CD1 may be increased to increase a capacitance of a first parasitic capacitor C-S1. The (1-2)-th gate electrode G1-22 may include at least a first portion P10 and a second portion P20 which are divided in the first direction DR1, where the first portion P10 at least overlaps the first output region SA1 or the first input region DA1 on a plane (e.g., is at least partially overlapped in the third direction DR3 by the first output region SA1 or the first input region DA1), and the second portion P20 at least overlaps the first channel region CA1 on a plane (e.g., is at least partially overlapped in the third direction DR3 by the first channel region CA1). For example, FIG. 6A shows example embodiments where the first portion P10 at least overlaps the first output region SA1 (e.g., is at least partially overlapped in the third direction DR3 by the first output region SA1), but in some example embodiments the first portion P10 at least the first input region DA1 (e.g., is at least partially overlapped in the third direction DR3 by at least the first input region DA1 such as shown in FIG. 7B).

The second portion P2 of the (1-1)-th gate electrode G1-21 overlapping (e.g., at least partially overlapped in the third direction DR3 by) the (1-2)-th gate electrode G1-22 has a low impact on the increase in capacitance of the first parasitic capacitor C-S1. As illustrated in FIG. 6A, a surface area (in a plane extending parallel to the top surface BSu) of the (1-1)-th gate electrode G1-21 has a low impact on the increase in capacitance of the first parasitic capacitor C-S1, and thus design of the (1-1)-th gate electrode G1-21 may be freely made.

Referring to FIG. 6B, a (1-1)-th gate electrode G1-21 and a (1-2)-th gate electrode G1-22 may be spaced apart from each other in the first direction DR1, for example such that the (1-1)-th gate electrode G1-21 and the (1-2)-th gate electrode G1-22 are exposed from each other in the third direction DR3. Some example embodiments in which the (1-1)-th gate electrode G1-21 and the (1-2)-th gate electrode G1-22 are spaced apart by a particular (or, alternatively, predetermined) distance DT is illustrated in FIG. 6B. As the particular (or, alternatively, predetermined) distance DT increases, a capacitance of at least one of a (1-1)-th parasitic capacitor CD1 and a (1-2)-th parasitic capacitor CD2 may decrease, and thus a capacitance of a first parasitic capacitor C-S1 may be decreased.

FIG. 7A is a plan view of a first transistor T1 according to some example embodiments of the present inventive concepts. FIG. 7B is a first cross-sectional view of a first transistor T1 according to some example embodiments of the present inventive concepts. FIG. 7C is a second cross-sectional view along line II-II′ in FIG. 7A of a first transistor T1 according to some example embodiments of the present inventive concepts. Hereinafter, FIGS. 4A to 6B are referenced for details of the same components as the components described with reference to FIGS. 4A to 6B.

Referring to FIGS. 7A to 7C, a (1-1)-th gate electrode G1-21 disposed at (e.g., directly on) the same layer as a (2-1)-th gate electrode G2-2 is disposed more adjacent to a first output region SA1 than a first input region DA1 on a first oxide semiconductor pattern OS1. For example, the (1-1)-th gate electrode G1-21 may be closer to the first output region SA1 than the first input region DA1 in a horizontal direction (e.g., at least one of the first direction DR1 or the second direction DR2) extending parallel to the top surface BSu of the base layer BS. On the first oxide semiconductor pattern OS1, a (1-2)-th gate electrode G1-22, which is disposed more adjacent to a first channel region CA1 than the (1-1)-th gate electrode G1-21 is, is disposed more adjacent to the first input region DA1 than the first output region SA1. For example, the (1-2)-th gate electrode G1-22 may be closer to the first channel region CA1 than the (1-1)-th gate electrode G1-21 in the horizontal direction, and the (1-2)-th gate electrode G1-22 may be closer to the first input region DA1 than the first output region SA1.

The (1-1)-th gate electrode G1-21 may include a first portion P1, a second portion P2, and a third portion P3 which are divided in the first direction DR1. The first portion P1 at least overlaps the first output region SA1 on a plane (e.g. is at least partially overlapped in the third direction DR3 by the first output region SA1), and the second portion P2 at least overlaps the first channel region CA1 on a plane (e.g. is at least partially overlapped in the third direction DR3 by the first channel region CA1). The second portion P2 is disposed more adjacent to the first input region DA1 than the first portion P1 is. For example, the second portion P2 may be closer than the first portion P1 to the first input region DA1 in a horizontal direction (e.g., at least one of the first direction DR1 or the second direction DR2) extending parallel to the top surface BSu of the base layer BS. The third portion P3 extends from the first portion P1 and overlaps a first connection electrode CNE1 (e.g. is at least partially overlapped in the third direction DR3 by the first connection electrode CNE1). The third portion P3 does not overlap the first oxide semiconductor pattern OS1 (e.g., is exposed from the first oxide semiconductor pattern OS1 in the third direction DR3).

The (1-2)-th gate electrode G1-22 may include a first portion P10, a second portion P20, and a third portion P30 which are divided in the first direction DR1. The first portion P10 at least overlaps the first input region DA1 on a plane (e.g., is at least partially overlapped in the third direction DR3 by the first input region DA1), and the second portion P20 at least overlaps the first channel region CA1 on a plane (e.g., is at least partially overlapped in the third direction DR3 by the first channel region CA1). The second portion P20 is disposed more adjacent to the first output region SA1 than the first portion P10 is. For example, the second portion P20 may be closer than the first portion P10 to the first output region SA1 in a horizontal direction (e.g., at least one of the first direction DR1 or the second direction DR2) extending parallel to the top surface BSu of the base layer BS. The third portion P30 extends from the second portion P20 and overlaps the first connection electrode CNE1 (e.g., is at least partially overlapped in the third direction DR3 by the first connection electrode CNE1). The third portion P30 does not overlap the first oxide semiconductor pattern OS1 (e.g., is exposed from the first oxide semiconductor pattern OS1 in the third direction DR3).

Compared to a (1-1)-th parasitic capacitor CD1, a (1-2)-th parasitic capacitor CD2 more significantly affects an increase and decrease in capacitance of a first parasitic capacitor C-S1. This is because the (1-2)-th gate electrode G1-22 is more adjacent to the first channel region CA1 than the (1-1)-th gate electrode G1-21 is (e.g., because the (1-2)-th gate electrode G1-22 is closer to the first channel region CA1 than the (1-1)-th gate electrode G1-21 in the horizontal direction).

The (1-1)-th gate electrode G1-21 may further extend from a top surface BSu of a base layer BS toward the first input region DA1 like FIG. 6A, and the (1-1)-th gate electrode G1-21 and the (1-2)-th gate electrode G1-22 may be spaced apart from each other in the first direction DR1 like FIG. 6B.

As stated above, the subthreshold swing (S.S.) may be increased to increase the low-grayscale driving voltage range of the first transistor T1, and as a result, the low-grayscale display quality (e.g., the low-grayscale display quality of the display device 11) may be improved.

Moreover, the driving current Ion (on current) of the first transistor T1 may be increased to decrease the driving voltage range (or the data swing range (DSR)) in the saturation region, and as a result, the power consumption (e.g., the power consumption of the display device 11) may be reduced.

In the above, description has been made with reference to some example embodiments of the present inventive concepts, but those skilled or of ordinary skill in the art or those having common knowledge in the art may understand that various modifications and changes may be made to the inventive concepts insofar as such modifications and changes do not depart from the spirit and technical scope of the inventive concepts set forth in the claims to be described later.

Therefore, the technical scope of the inventive concepts is not to be limited to the contents stated in the detailed description of the specification, but should be determined by the claims.

What is claimed is:

1. A display device, comprising:
a base layer;
a plurality of insulating layers on the base layer;
a first transistor on the base layer; and
a light emitting element electrically connected to the first transistor,
wherein the first transistor includes
a first oxide semiconductor pattern, the first oxide semiconductor pattern including a first input region, a first output region, and a first channel region between the first input region and the first output region,
a first gate electrode above the first channel region and at least partially overlapping the first channel region in a vertical direction, the vertical direction extending perpendicular to a top surface of the base layer,
a (1-1)-th gate electrode below the first channel region, the (1-1)-th gate electrode at least partially overlapped by the first channel region in the vertical direction and electrically connected to the first output region, and
a (1-2)-th gate electrode below the first channel region, the (1-2)-th gate electrode at least partially overlapped by the first channel region in the vertical direction and electrically connected to the first output region,
wherein the (1-1)-th gate electrode and the (1-2)-th gate electrode are at different layers such that one of the (1-1)-th gate electrode or the (1-2)-th gate electrode is closer to the top surface of the base layer than another one of the (1-1)-th gate electrode or the (1-2)-th gate electrode in the vertical direction.

2. The display device of claim 1, further comprising a connection electrode on the base layer and configured to electrically connect the first output region, the (1-1)-th gate electrode, and the (1-2)-th gate electrode.

3. The display device of claim 2, wherein the plurality of insulating layers comprise:
a first insulating layer on the (1-1)-th gate electrode;
a second insulating layer on the first insulating layer and the (1-2)-th gate electrode such that the first insulating layer is between the (1-1)-th gate electrode and both the second insulating layer and the (1-2)-th gate electrode in the vertical direction; and
a third insulating layer on the second insulating layer and the first oxide semiconductor pattern.

4. The display device of claim 3, wherein:
the connection electrode is connected to the (1-1)-th gate electrode through a first contact hole passing through the first insulating layer, the second insulating layer, and the third insulating layer,
the connection electrode is connected to the (1-2)-th gate electrode through a second contact hole passing through the second insulating layer and the third insulating layer, and
the connection electrode is connected to the first output region through a third contact hole passing through the third insulating layer.

5. The display device of claim 4, wherein the first contact hole and the second contact hole are spaced apart from the first gate electrode and the first oxide semiconductor pattern in one or more horizontal directions extending parallel to the top surface of the base layer.

6. The display device of claim 1, wherein:
the (1-1)-th gate electrode is closer than the (1-2)-th gate electrode to the base layer in the vertical direction,
a first portion of the (1-1)-th gate electrode is at least partially overlapped by the first input region in the vertical direction, and a second portion of the (1-1)-th gate electrode is at least partially overlapped by the first channel region in the vertical direction, and
a first portion of the (1-2)-th gate electrode is at least partially overlapped by the first output region in the vertical direction, and a second portion of the (1-2)-th gate electrode is at least partially overlapped by the first channel region in the vertical direction.

7. The display device of claim 1, wherein:
the (1-1)-th gate electrode is closer than the (1-2)-th gate electrode to the base layer in the vertical direction,
a first portion of the (1-1)-th gate electrode is at least partially overlapped by the first output region in the vertical direction, and a second portion of the (1-1)-th gate electrode is at least partially overlapped by the first channel region in the vertical direction, and
a first portion of the (1-2)-th gate electrode is at least partially overlapped by the first input region in the vertical direction, and a second portion of the (1-2)-th gate electrode is at least partially overlapped by the first channel region in the vertical direction.

8. The display device of claim 1, wherein:
the (1-1)-th gate electrode is closer than the (1-2)-th gate electrode to the base layer in the vertical direction,
the (1-1)-th gate electrode comprises a first portion at least partially overlapped by the first input region in the vertical direction, a second portion at least partially overlapped by the first channel region in the vertical direction, and a third portion at least partially overlapped by the first output region in the vertical direction, and
the (1-2)-th gate electrode comprises a first portion at least partially overlapped by the first input region or the first output region in the vertical direction, and a second portion at least partially overlapped by the first channel region in the vertical direction.

9. The display device of claim 1, wherein a portion of the (1-1)-th gate electrode and a portion of the (1-2)-th gate electrode at least partially overlap each other in the vertical direction.

10. The display device of claim 1, wherein the (1-1)-th gate electrode and the (1-2)-th gate electrode are spaced apart from each other in one or more horizontal directions extending parallel to the top surface of the base layer.

11. The display device of claim 1, further comprising a second transistor on the base layer,
wherein the second transistor comprises:
a second oxide semiconductor pattern comprising a second input region, a second output region, and a second channel region, the second channel region between the second input region and the second output region;
a second gate electrode above the second channel region and overlapping the second channel region in the vertical direction; and
a (2-1)-th gate electrode below the second channel region, the (2-1)-th gate electrode at least partially overlapped by the second channel region in the vertical direction and electrically connected to the second gate electrode,
wherein a first separation distance in the vertical direction between the first channel region and the (1-2)-th gate electrode is smaller than a second separation distance in the vertical direction between the second channel region and the (2-1)-th gate electrode.

12. The display device of claim 11, wherein the (2-1)-th gate electrode is at a same layer as the (1-1)-th gate electrode and comprises a same material as the (1-1)-th gate electrode.

13. The display device of claim 12, further comprising a connection electrode configured to electrically connect the second gate electrode and the (2-1)-th gate electrode,
wherein the plurality of insulating layers comprises:
first and second insulating layers on the (2-1)-th gate electrode; and
a third insulating layer on the second oxide semiconductor pattern and the second gate electrode,
wherein a portion of the connection electrode is on the third insulating layer.

14. The display device of claim 1, wherein the (1-1)-th gate electrode and the (1-2)-th gate electrode collectively define a lower gate electrode, and the display device further comprises a capacitor electrically connected between the lower gate electrode and the first channel region.

15. An electronic device, comprising:
a display device; and
a processor configured to control the display device,
wherein the display device includes
a base layer,
a plurality of insulating layers on the base layer,
a first transistor on the base layer, and
a light emitting element electrically connected to the first transistor, wherein the first transistor includes
a first oxide semiconductor pattern including a first input region, a first output region, and a first channel region between the first input region and the first output region,
a first gate electrode above the first channel region and at least partially overlapping the first channel region in a vertical direction, the vertical direction extending perpendicular to a top surface of the base layer,
a (1-1)-th gate electrode below the first channel region, the (1-1)-th gate electrode at least partially overlapped by the first channel region in the vertical direction and electrically connected to the first output region, and
a (1-2)-th gate electrode below the first channel region, the (1-2)-th gate electrode at least partially overlapped by the first channel region in the vertical direction and electrically connected to the first output region,
wherein the (1-1)-th gate electrode and the (1-2)-th gate electrode are at different layers such that one of the (1-1)-th gate electrode or the (1-2)-th gate electrode is closer to the top surface of the base layer than another one of the (1-1)-th gate electrode or the (1-2)-th gate electrode in the vertical direction.

16. The electronic device of claim 15, further comprising a connection electrode on the base layer and configured to electrically connect the first channel region, the (1-1)-th gate electrode, and the (1-2)-th gate electrode.

17. The electronic device of claim 15, wherein:
the (1-1)-th gate electrode is closer than the (1-2)-th gate electrode to the base layer in the vertical direction,
a first portion of the (1-1)-th gate electrode is at least partially overlapped by the first input region in the vertical direction, and a second portion of the (1-1)-th gate electrode is at least partially overlapped by the first channel region in the vertical direction, and
a first portion of the (1-2)-th gate electrode is at least partially overlapped by the first output region in the vertical direction, and a second portion of the (1-2)-th gate electrode is at least partially overlapped by the first channel region in the vertical direction.

18. The electronic device of claim 15, wherein:
the (1-1)-th gate electrode is closer than the (1-2)-th gate electrode to the base layer in the vertical direction,
a first portion of the (1-1)-th gate electrode is at least partially overlapped by the first output region in the vertical direction, and a second portion of the (1-1)-th gate electrode is at least partially overlapped by the first channel region in the vertical direction, and
a first portion of the (1-2)-th gate electrode is at least partially overlapped by the first input region in the vertical direction, and a second portion of the (1-2)-th gate electrode is at least partially overlapped by the first channel region in the vertical direction.

19. The electronic device of claim 15, wherein:
the (1-1)-th gate electrode is closer than the (1-2)-th gate electrode to the base layer in the vertical direction,
the (1-1)-th gate electrode comprises a first portion at least partially overlapped by the first input region in the vertical direction, a second portion at least partially overlapped by the first channel region in the vertical direction, and a third portion at least partially overlapped by the first output region in the vertical direction, and
the (1-2)-th gate electrode comprises a first portion at least partially overlapped by the first input region or the first output region in the vertical direction, and a second portion at least partially overlapped by the first channel region in the vertical direction.

20. The electronic device of claim 15, further comprising a second transistor on the base layer,
wherein the second transistor comprises:
a second oxide semiconductor pattern comprising a second input region, a second output region, and a second channel region, the second channel region between the second input region and the second output region;
a second gate electrode above the second channel region and overlapping the second channel region in the vertical direction; and
a (2-1)-th gate electrode below the second channel region, the (2-1)-th gate electrode at least partially overlapped by the second channel region in the vertical direction and electrically connected to the second gate electrode,
wherein a first separation distance in the vertical direction between the first channel region and the (1-2)-th gate electrode is smaller than a second separation distance in the vertical direction between the second channel region and the (2-1)-th gate electrode.
